(19) United States
(12) Patent Application Publication
(10) Pub. No.: US 2021/0359116 A1
(43) Pub. Date: Nov. 18, 2021

(54) SEMICONDUCTOR APPARATUS

(71) Applicant: FUJI ELECTRIC CO., LTD., Kanagawa (JP)

(72) Inventors: Kosuke YOSHIDA, Matsumoto-city (JP); Nao SUGANUMA, Matsumoto-city (JP)

(21) Appl. No.: 17/210,492

(22) Filed: Mar. 23, 2021

(30) Foreign Application Priority Data
May 15, 2020 (JP) 2020-086231

(51) Int. Cl. H01L 29/739; H01L 29/06; H01L 29/08; H01L 27/06; H01L 29/866

(52) U.S. Cl. CPC H01L 29/7397; H01L 29/0619; H01L 29/866; H01L 27/0629; H01L 27/0664; H01L 29/0804

(57) ABSTRACT

Provided is a semiconductor apparatus comprising: an emitter region having a first conductivity type provided on a front surface of a semiconductor substrate; a first gate trench part and a second gate trench part in contact with the emitter region; a first emitter non-contact trench part and a second emitter non-contact trench part out of contact with the emitter region; a gate pad for setting the first gate trench part, the second gate trench part, the first emitter non-contact trench part, and the second emitter non-contact trench part to gate potential; and a diode having an anode connected to the gate pad and a cathode connected to the first emitter non-contact trench part and the second emitter non-contact trench part, wherein the first gate trench part, the first emitter non-contact trench part, the second gate trench part, and the second emitter non-contact trench part are adjacently arranged in order.

The contents of the following Japanese patent applications are incorporated herein by reference:

No. 2020-086231 filed in JP on May 15, 2020.

### BACKGROUND

### 1. Technical Field

The present invention relates to a semiconductor apparatus.

### 2. Related Art

Patent Document 1 describes “Provided is a semiconductor apparatus that suppresses current for charging gate-emitter capacitor without going through a gate resistor and has improved controllability of dV/dt due to the gate resistor.”

### PRIOR ART DOCUMENT

### Patent Document

Patent Document 1: WO2017/126167

### BRIEF DESCRIPTION OF THE DRAWINGS

FIG. 1A shows an example of a top view of a semiconductor apparatus 100.

FIG. 1B shows an example of a cross-sectional view of the semiconductor apparatus 100.

FIG. 2A shows an example of a cross-sectional view of a semiconductor apparatus 200.

FIG. 2B shows an example of an equivalent circuit diagram of the semiconductor apparatus 200.

FIG. 2C shows an example of current and voltage waveforms at the time of switching of the semiconductor apparatus 200.

FIG. 3A shows an example of a cross-sectional view of a semiconductor apparatus 300 according to a comparative example 1.

FIG. 3B shows an example of an equivalent circuit diagram of the semiconductor apparatus 300 according to the comparative example 1.

FIG. 3C shows an example of current and voltage waveforms at the time of switching of the semiconductor apparatus 300 according to the comparative example 1.

FIG. 4A shows an example of a cross-sectional view of a semiconductor apparatus 400 according to a comparative example 2.

FIG. 4B shows an example of an equivalent circuit diagram of the semiconductor apparatus 400 according to the comparative example 2.

FIG. 4C shows an example of current and voltage waveforms at the time of switching of the semiconductor apparatus 400 according to the comparative example 2.

FIG. 5 shows another example of the cross-sectional view of the semiconductor apparatus 100.

FIG. 6A shows an example of a top view of a diode 110.

FIG. 6B shows another example of a cross-sectional view of the diode 110.

FIG. 7A shows yet another example of the cross-sectional view of the diode 110.

FIG. 7B shows another example of the top view of the diode 110.

FIG. 8 shows an example of an enlarged view of the upper surface of the semiconductor apparatus 100.

FIG. 9A shows another example of the top view of the semiconductor apparatus 100.

FIG. 9B shows another example of the enlarged view of the upper surface of the semiconductor apparatus 100.

FIG. 9C shows an example of a cross-sectional view in an extending direction of a trench part of the semiconductor apparatus 100.

FIG. 10A shows an example of a cross-sectional view of a semiconductor apparatus 500.

FIG. 10B shows an example of a diagram of equipotential lines in the cross-sectional view of the semiconductor apparatus 500.

FIG. 10C shows an example of a contour diagram of a current value in the cross-sectional view of the semiconductor apparatus 500.

FIG. 11A shows an example of current and voltage waveforms at the time of switching of the semiconductor apparatus 500.

FIG. 11B shows an example of a graph of a power loss per unit time at the time of switching of the semiconductor apparatus 500.

FIG. 12A shows another example of the current and voltage waveforms at the time of switching of the semiconductor apparatus 300.

FIG. 12B shows an example of a graph of a power loss per unit time at the time of switching of the semiconductor apparatus 300.

FIG. 13A shows another example of the current and voltage waveforms at the time of switching of the semiconductor apparatus 200.

FIG. 13B shows an example of a graph of power loss per unit time at the time of switching of the semiconductor apparatus 200.

FIG. 14 shows an example of a graph of switching losses of the semiconductor apparatus 200, the semiconductor apparatus 300, and the semiconductor apparatus 500.

FIG. 15 shows an example of a cross-sectional view of a semiconductor apparatus 600 according to a comparative example 3.

FIG. 16 shows an example of a cross-sectional view of a semiconductor apparatus 700 according to a comparative example 4.

FIG. 17 shows an example of a graph of switching losses of the semiconductor apparatus 200, the semiconductor apparatus 600, and the semiconductor apparatus 700.

FIG. 18 shows an example of a graph of a doping concentration of a storage region and a switching loss.

FIG. 19A shows an example of current and voltage waveforms at the time of switching of the semiconductor apparatus 600 or the semiconductor apparatus 700.

FIG. 19B shows an example of a graph of an on-state power loss P_{c} [W] per unit time at the time of switching of the semiconductor apparatus 600 or the semiconductor apparatus 700.

FIG. 19C shows a reverse recovery characteristic (diode anode voltage Va [V]) of the diode 110 at the time of switching of the semiconductor apparatus 600 or the semiconductor apparatus 700.

FIG. 20A shows another example of the current and voltage waveforms at the time of switching of the semiconductor apparatus 200.

FIG. 20B shows an example of a graph of an on-state power loss P_{C} [W] per unit time at the time of switching of the semiconductor apparatus 200.

FIG. 20C shows a reverse recovery characteristic (diode anode voltage Va [V]) of the diode 110 at the time of switching of the semiconductor apparatus 200.

FIG. 21A shows another example of the current and voltage waveforms at the time of switching of the semiconductor apparatus 200.

FIG. 21B shows another example of the graph of the on-state power loss P_{C} [W] per unit time at the time of switching of the semiconductor apparatus 200.

FIG. 21C shows another example of the reverse recovery characteristic (diode anode voltage Va [V]) of the diode 110 at the time of switching of the semiconductor apparatus 200.

### DESCRIPTION OF EXEMPLARY EMBODIMENTS

Hereinafter, the present invention will be described through embodiments of the invention, but the following embodiments do not limit the claimed invention. Moreover, not all combinations of features described in the embodiments are necessary to solutions of the invention.

As used herein, one side in a direction parallel to the depth direction of a semiconductor substrate is referred to as “upper”, and the other side “lower”. Moreover, out of two principal surfaces of a substrate, a layer, or other members, one surface is referred to as the “upper surface”, and the other surface the “lower surface”. “Upper” and “lower” directions are not limited to the direction of gravity, or a direction in which a semiconductor apparatus is mounted.

In this specification, technical matters may be described using orthogonal coordinate axes of an X axis, a Y axis, and a Z axis. The orthogonal coordinate axes merely specify relative positions of components, and do not limit a specific direction. For example, the Z axis direction is not limited to the height direction with respect to the ground, that is, the direction of gravity. In this specification, a surface parallel to a front surface of the semiconductor substrate represents an XY surface, and a direction that forms a right-handed system with the X axis and the Y axis and is the depth direction of the semiconductor substrate represents the Z axis Note that, as used herein, a case where the semiconductor substrate is viewed in the Z axis direction may be referred to as a “planar view”.

Each embodiment example shows an example where a first conductivity type is N type and a second conductivity type is P type. However, the first conductivity type may be P type and the second conductivity type may be N type. In this case, conductivity types of substrates, layers, regions, or the like in each embodiment example are of opposite polarity.

In this specification, it is meant that an electron or a hole is respectively a majority carrier in a layer or region labeled n or p. Moreover, a layer or region with + and − attached to n and p means to respectively have doping concentrations higher and lower than that of a layer or region without them attached; and a layer or region with ++ attached means to have a doping concentration higher than that of a layer or region with + attached, and a layer or region with −− attached means to have a doping concentration lower than that of a layer or region with − attached.

As used herein, a doping concentration refers to a concentration of a donor or an acceptorized dopant. Therefore, the unit is/cm³. A unit system herein is the SI unit system unless otherwise noted. Although a unit of length may be indicated in cm, calculations may be carried out after conversion to meters (m).

As used herein, concentration difference (that is, a net doping concentration) between a donor and an acceptor may be referred to as a doping concentration. In this case, the doping concentration can be measured by capacitance-voltage method (CV method), SR method, or the like. Moreover, a chemical concentration of the donor and the acceptor may also be a doping concentration. In this case, the doping concentration can be measured by SIMS method. Unless otherwise limited, any of the above may be used as a doping concentration. Unless otherwise limited, a peak value of doping concentration distribution in a doping region may be a doping concentration in said doping region. Each concentration herein may be a value at room temperature. As the value at room temperature, a value at 300K (Kelvin) (about 26.9 degrees C.) for example may be used.

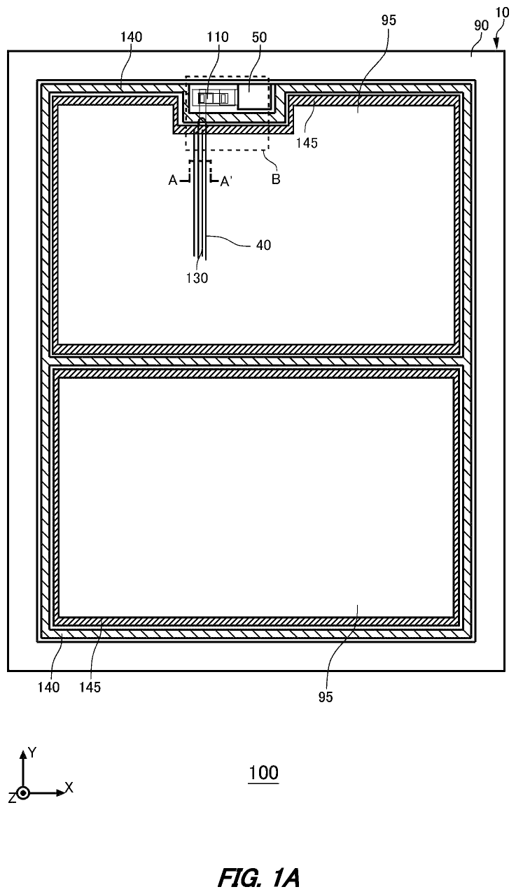

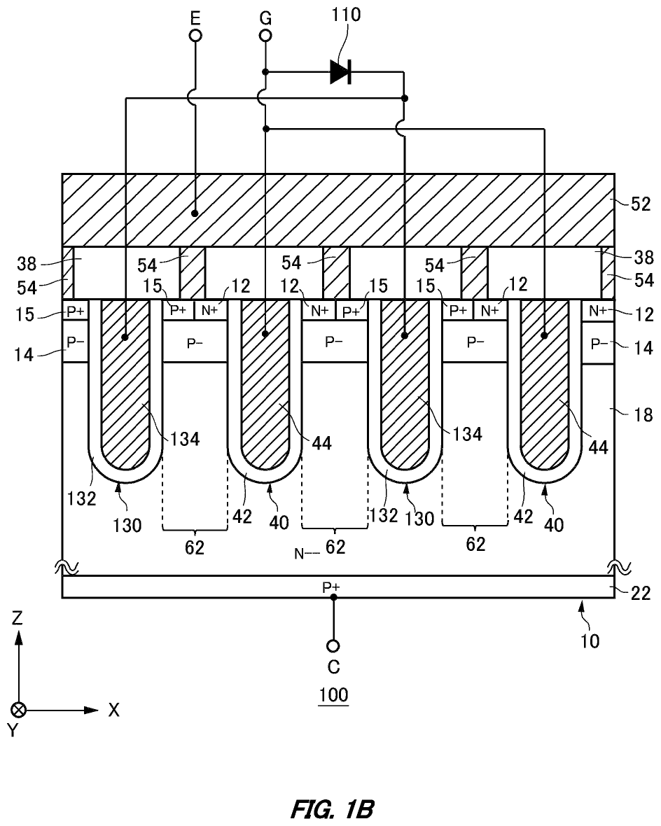

FIG. 1A is an example of a top view of a semiconductor apparatus 100. The semiconductor apparatus 100 is a semiconductor chip according to an embodiment example. The semiconductor apparatus 100 in this example is an insulated gate bipolar transistor (IGBT). However, the semiconductor apparatus 100 is not limited to the IGBT, and may also be a vertical metal-oxide-semiconductor field effect transistor (VMOSFET) or a RC (reverse conducting)-IGBT.

A semiconductor substrate 10 may be a silicon substrate, a silicon carbide substrate, or a nitride semiconductor substrate such as gallium nitride or the like. The semiconductor substrate 10 in this example is a silicon substrate.

The semiconductor apparatus 100 includes, on the upper surface of the semiconductor substrate 10, an edge termination structure part 90, a gate pad 50, a gate runner 140 going around inside the edge termination structure part 90, an active region 95 provided inside the gate runner, and a gate metal layer 145 going around the outermost part of the active region 95. The semiconductor apparatus 100 further includes a diode 110 having an anode connected to the gate pad 50. The diode 110 in this example is provided adjacent to the gate pad 50, but a position where the diode 110 is provided is not limited to this position.

The semiconductor apparatus 100 includes, on the upper surface of the semiconductor substrate 10, the edge termination structure part 90, the gate pad 50, the gate runner 140 going around inside the edge termination structure part 90, and the active region 95 provided inside the gate runner 140. The semiconductor apparatus 100 further includes, on the outermost part of the active region 95, the gate metal layer 145 going around the upper surface of the active region 95.

The edge termination structure part 90 relaxes electric field concentration on the upper surface side of the semiconductor substrate 10. The edge termination structure part 90 has a structure of, for example, a guard ring, a field plate, a RESURF, and a combination thereof.

The gate pad 50 is electrically connected to the diode 110. The gate pad 50 is formed of material containing metal. At least a partial region of the gate pad 50 may be formed of aluminum, aluminum-silicon alloy, or aluminum-silicon-copper alloy. An emitter electrode 52 and the gate pad 50 may have, in a layer underlying a region formed of aluminum or the like, barrier metal formed of titanium, titanium compound, or the like.

In the diode 110, a cathode electrode 112 described later is extended to be connected to the gate metal layer 145. However, the cathode electrode 112 and the gate metal layer 145 may be integrally molded.

In this example, a gate trench part 40 and an emitter non-contact trench part 130 are arranged in the X direction. In particular, in this example, the gate trench part 40 and the emitter non-contact trench part 130 have an arrangement ratio of 1:1, and are alternately arranged.

The gate trench part 40 is electrically connected to the gate runner 140. On the other hand, the emitter non-contact trench part 130 is electrically connected to the gate metal layer.

On a front surface of the semiconductor substrate 10, the gate runner 140 goes around inside the gate pad 50 and the diode 110 and outside the active region 95 and the gate metal layer 145. That is, the gate runner 140 may be provided between the gate pad 50 and a plurality of trench parts. The gate runner 140 is electrically connected to the gate pad 50. The gate runner 140 in this example is formed of polysilicon.

The gate metal layer 145 goes around inside the gate runner 140. On the front surface of the semiconductor substrate 10, the gate metal layer 145 goes around the outermost part of the active region 95. The gate metal layer 145 may be a wiring layer formed of metal.

FIG. 1B is an example of a cross-sectional view of the semiconductor apparatus 100. The semiconductor apparatus 100 in this example includes an N+ type emitter region 12 provided on the front surface of a semiconductor substrate 10. Further, the semiconductor apparatus 100 includes four trench parts arranged in the X axis direction.

The semiconductor apparatus 100 includes two gate trench parts 40, two emitter non-contact trench parts 130, an emitter electrode 52, an interlayer dielectric film 38, and a contact hole 54. The semiconductor apparatus 100 further includes a mesa part 62 between the gate trench part 40 and the emitter non-contact trench part 130.

The semiconductor substrate 10 includes therein a P+ type collector region 22, an N− type drift region 18 laminated above the collector region 22, a P− type base region 14 provided above the drift region 18, a P+ type contact region 15 provided above the base region 14, and an N+ type emitter region 12 provided above the base region 14. In the semiconductor substrate, the base region 14 may be provided in contact with and below the emitter region 12, and the drift region 18 may be provided in contact with and below the base region 14. However, when the semiconductor apparatus 100 is a VMOSFET, the collector region 22 may be omitted.

In the semiconductor apparatus 100 of this example, the base region 14 is in contact with the drift region 18. In an IGBT device, in order to improve Injection Enhancement effect of a carrier, an N type storage region having a doping concentration higher than that of the drift region 18 may be provided between the base region 14 and the drift region, but in this example, no storage region is provided. This allows gate voltage to rise gently, and can avoid excessive electric field concentration, overcurrent density, and a high switching loss in the mesa part 62.

The semiconductor apparatus 100 includes, in order from the negative side to the positive side in the X axis direction, the emitter non-contact trench part 130 out of contact with the emitter region 12, the gate trench part 40 in contact with the emitter region 12, and the emitter non-contact trench part 130, and the gate trench part 40. These trench parts are, in order from the negative side in the X axis direction to the positive side in the X axis direction, an example of a first emitter non-contact trench part 130, a first gate trench part 40, a second emitter non-contact trench part 130, and a second gate trench part 40.

The semiconductor apparatus 100 includes a gate terminal G for setting the two gate trench parts 40 and the two emitter non-contact trench parts 130 to gate potential V_{g}. The gate terminal G is a terminal for externally connecting the semiconductor apparatus 100, and the gate pad 50 is an example of the gate terminal G. However, the gate terminal G only needs to be an external connection terminal, and is not limited to a pad.

The semiconductor apparatus 100 includes the emitter electrode 52 above the trench parts. The emitter electrode 52 is set to emitter potential Vₑ. The emitter potential Vₑ may be set to ground potential.

On the front surface of the semiconductor substrate 10, the emitter region 12 is extended from the gate trench part 40 provided on the most negative side of the X axis, to a direction of the adjacent emitter non-contact trench part 130 on the positive side of the X axis. The emitter region 12 is terminated without reaching said emitter non-contact trench part 130.

On the front surface of the semiconductor substrate, the emitter region 12 is extended from the gate trench part 40 arranged in the third position from the negative side of the X axis, to a direction of the adjacent emitter non-contact trench part 130 on the negative side of the X axis. The emitter region 12 is terminated without reaching said emitter non-contact trench part 130.

On the front surface of the semiconductor substrate, the emitter region 12 is extended from the gate trench part 40 arranged in the third position from the negative side of the X axis, to the direction of the adjacent emitter non-contact trench part 130 on the positive side of the X axis. The emitter region 12 is terminated without reaching said emitter non-contact trench part 130.

The interlayer dielectric film 38 insulates conductive parts inside the different trench parts and the emitter electrode 52. The interlayer dielectric film 38 may cover the upper part of each trench part. The contact hole 54 is provided so as to penetrate the interlayer dielectric film 38.

The gate trench part 40 includes a gate dielectric film 42 and a gate conductive part 44. The gate conductive part 44 is electrically connected to the gate pad 50, and is set to the gate potential V_{g}. The gate potential V_{g} may be potential higher than the emitter potential Vₑ. In the mesa part 62, an NPN structure is formed in a region in contact with the gate dielectric film 42, by the emitter region 12, the base region 14, and the drift region 18. Therefore, when the gate conductive part 44 is set to the gate potential V_{g}, an N type channel is formed in the base region 14 and operates as a transistor.

The emitter non-contact trench part 130 includes an emitter non-contact trench dielectric film 132 and an emitter non-contact trench conductive part 134. The emitter non-contact trench conductive part 134 is also electrically connected to the gate pad 50, and is set to the gate potential V_{g}. However, the emitter non-contact trench part 130 is out of contact with the emitter region 12. On the front surface of the semiconductor substrate 10, the emitter non-contact trench part 130 is in contact with the base region 14 or the contact region 15. Therefore, in the mesa part 62, even if the emitter non-contact trench conductive part 134 is set to the gate potential V_{g}, no channel is formed around the emitter non-contact trench part 130 or operates as a transistor.

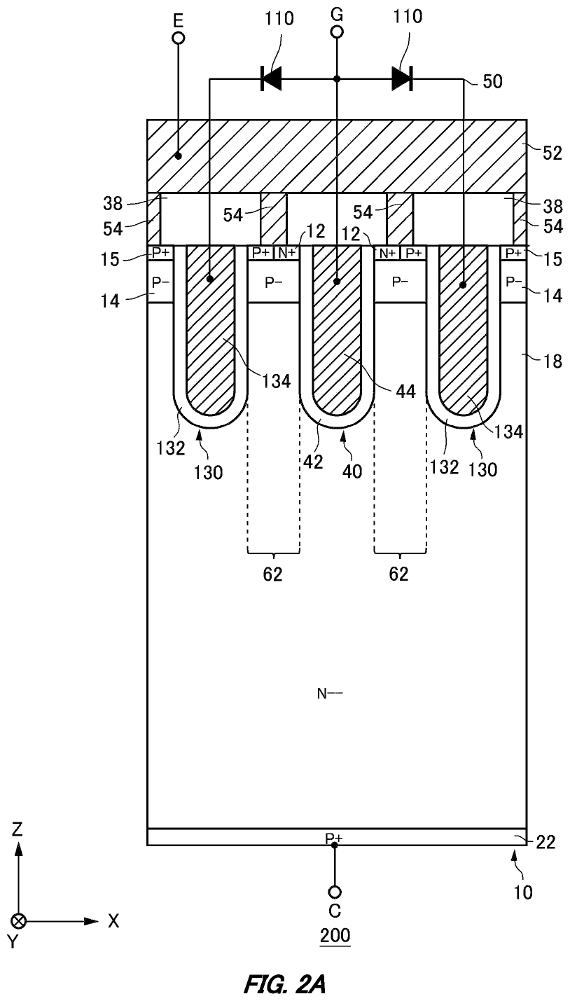

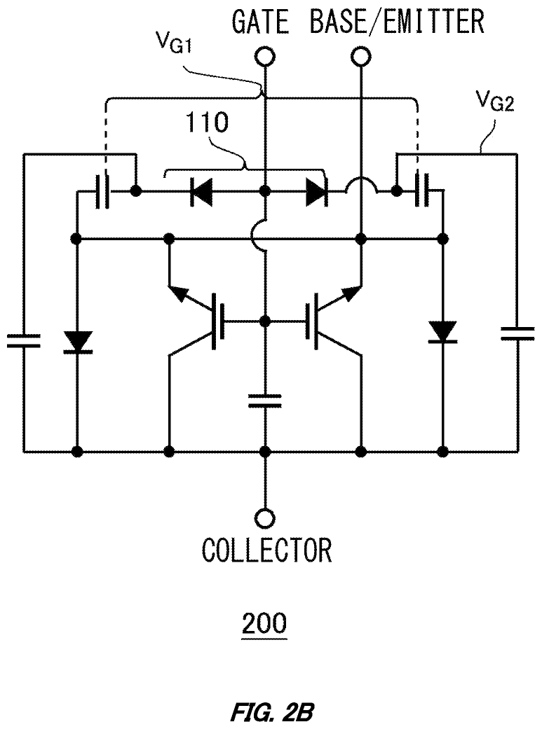

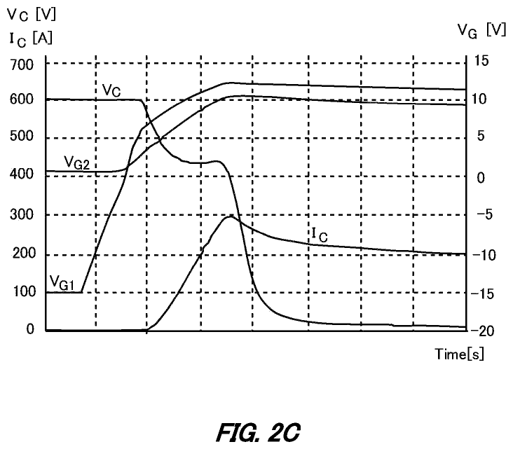

FIG. 2A shows an example of a cross-sectional view of a semiconductor apparatus 200. The semiconductor apparatus 200 is a part of the semiconductor apparatus 100.

The semiconductor apparatus 200 includes three trench parts arranged in the X axis direction: an emitter non-contact trench part 130, a gate trench part 40, and an emitter non-contact trench part 130.

The semiconductor apparatus 200 includes diodes 110 between the emitter non-contact trench parts 130 and a gate terminal G. The diodes between the emitter non-contact trench parts 130 and the gate terminal G may be the same or different diodes.

FIG. 2B shows an example of an equivalent circuit diagram of the semiconductor apparatus 200. In this example, a diode 110 is provided between a gate capacitor of an emitter non-contact trench part 130 and a gate terminal G.

The emitter non-contact trench part 130 is equivalent to a diode including a gate capacitor to be charged and a parasitic capacitor. The gate capacitor to be charged of the emitter non-contact trench part 130 is electrically connected to a cathode of the diode 110. An anode of the diode 110 is electrically connected to the gate terminal G.

The diode 110 prevents current from flowing back from the gate capacitor of the emitter non-contact trench part 130 to the gate terminal G. This improves, in operation at the time of switching on of an IGBT, a charging speed of the emitter non-contact trench part 130. Therefore, potential of a mesa part 62 can be quickly increased, and operation of the entire semiconductor apparatus 100 is accelerated. This reduces a time rate of change dV_{C}/dt in emitter-collector voltage of the IGBT and a switching-on power loss.

In this example, voltage between gate capacitors of the emitter non-contact trench part 130 is set to V_{G1}, and voltage around the parasitic capacitor of the emitter non-contact trench part 130 is set to V_{G2}.

FIG. 2C shows current and voltage waveforms at the time of switching of the semiconductor apparatus 200. Emitter-collector voltage V_{C}, emitter-collector current I_{C}, and potential V_{G} of a gate conductive part 44 are shown.

V_{G2} is higher than V_{G1} from a start of driving, since presence of a diode 110 prevents a carrier from flowing back to a gate terminal G. This accelerates a start of switching-on operation, and causes the V_{C} and the I_{C} to perform stable start-up operation with less vibration. Therefore, a switching-on power loss expressed as a product of the V_{C} and the I_{C} is reduced.

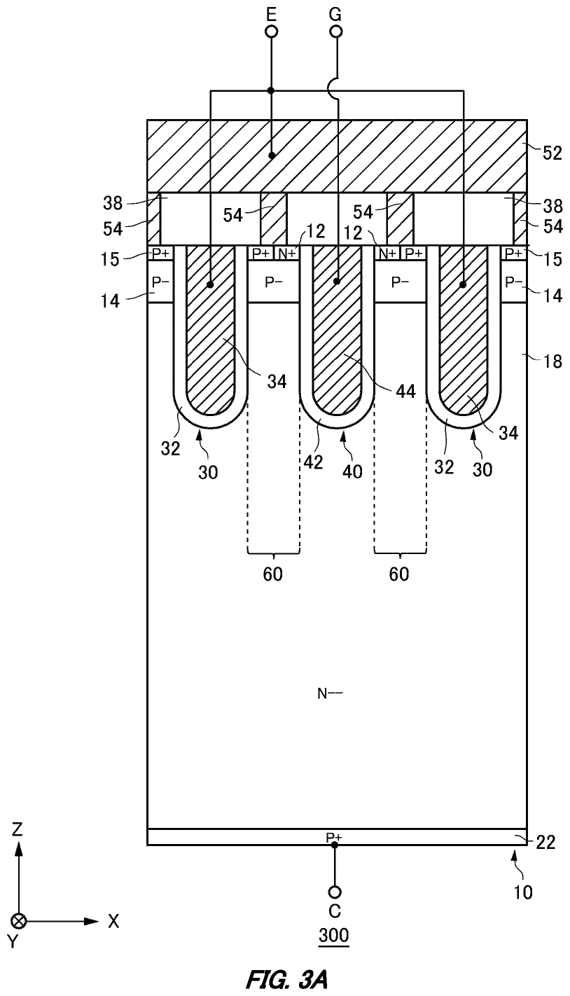

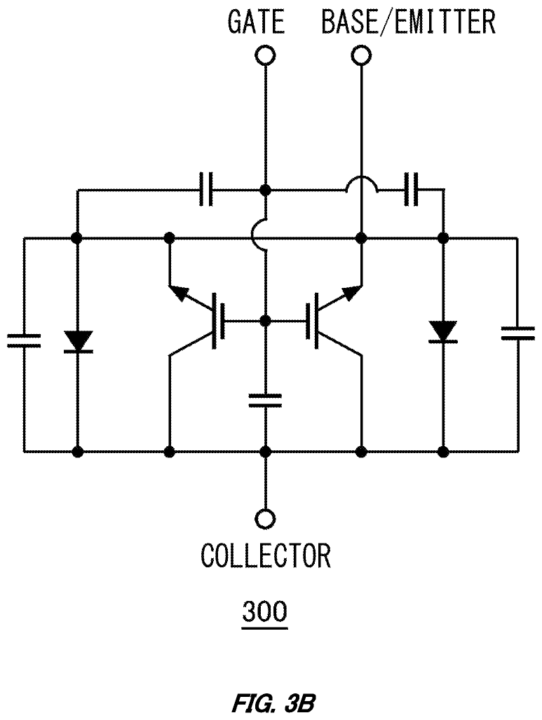

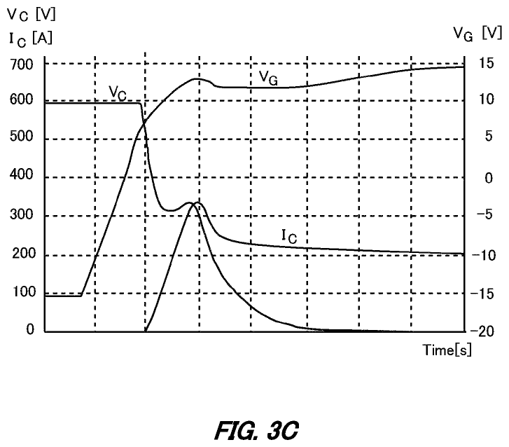

FIG. 3A shows an example of a cross-sectional view of a semiconductor apparatus 300 according to a comparative example 1. The semiconductor apparatus 300 includes three trench parts arranged in the X axis direction: a dummy trench part 30, a gate trench part 40, and a dummy trench part 30.

The semiconductor apparatus 300 includes, in a semiconductor substrate 10, a mesa part 60 between the dummy trench part 30 and the gate trench part 40. The dummy trench part 30 in this example is in contact with a contact region 15, but the dummy trench part 30 may be in contact with an emitter region 12.

The dummy trench part 30 includes a dummy dielectric film 32 and a dummy conductive part 34. The dummy conductive part 34 is electrically connected to an emitter terminal E, and is set to emitter potential Vₑ. Since no gate voltage is applied to the dummy trench part 30, no channel is formed in a region of the mesa part 60 in contact with the dummy trench part 30.

FIG. 3B shows an example of an equivalent circuit diagram of the semiconductor apparatus 300 according to the comparative example 1. The example in FIG. 2B and this example are different in connection relationship between the gate terminal G and the emitter terminal E, and the gate capacitor and the parasitic capacitor of the dummy trench part 30, and in presence/absence of the diode 110 between the gate terminal G and the gate capacitor of the dummy trench part 30.

FIG. 3C shows an example of current and voltage waveforms at the time of switching of the semiconductor apparatus 300 according to the comparative example 1. In the semiconductor apparatus 300, since it can be driven even without increasing potential of the dummy conductive part 34 to the gate potential V_{g}, switching-on start timing is accelerated. On the other hand, inclination of emitter-collector voltage V_{C} and amplitude of emitter-collector current I_{C} is increased. This increases a switching-on power loss.

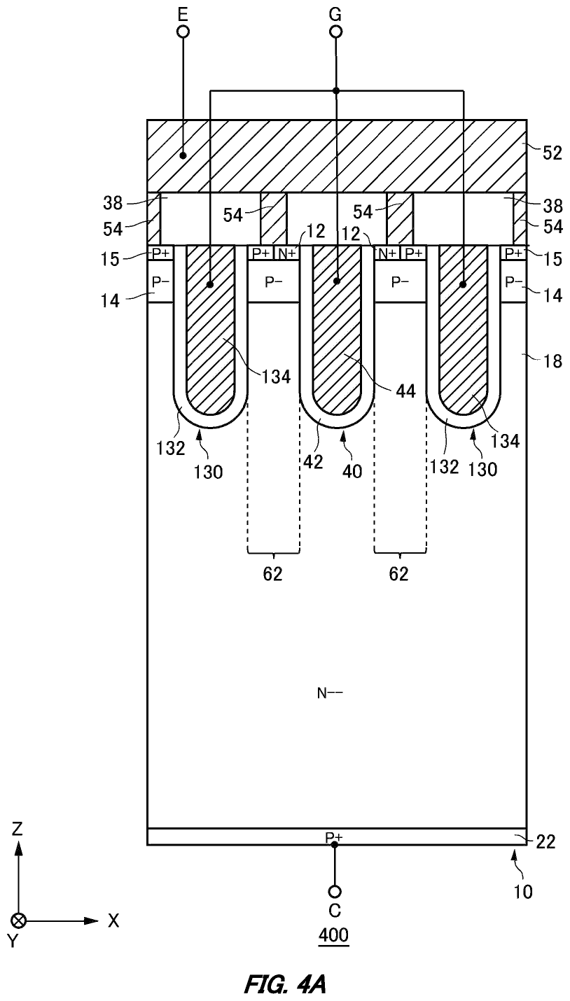

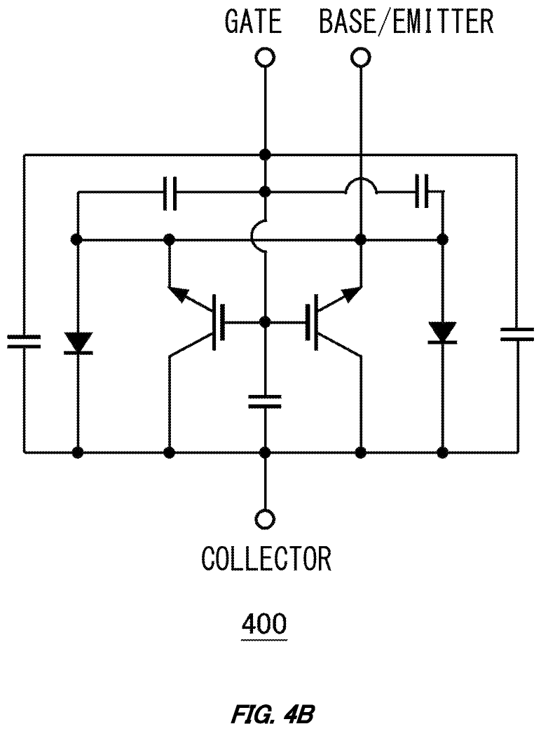

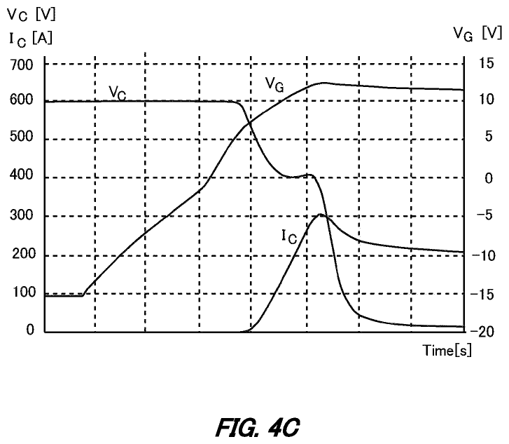

FIG. 4A shows an example of a cross-sectional view of a semiconductor apparatus 400 according to a comparative example 2. The semiconductor apparatus 400 includes an emitter non-contact trench part 130, a gate trench part 40, and an emitter non-contact trench part 130, arranged from the negative side in the X axis direction to the positive side in the X axis direction. The semiconductor apparatus 400 in this example is different from the semiconductor apparatus 100 in that it has no diode 110 connected between a gate terminal G and an emitter non-contact trench conductive part 134.

FIG. 4B shows an example of an equivalent circuit diagram of the semiconductor apparatus 400 according to the comparative example 2. In order to drive the semiconductor apparatus 400, three gate capacitors: a gate capacitor of the gate trench part 40 and gate capacitors of the two emitter non-contact trench parts 130 are charged.

FIG. 4C shows an example of current and voltage waveforms at the time of switching of the semiconductor apparatus 400 according to the comparative example 2. In the semiconductor apparatus 400, since it is driven after the three gate capacitors are charged, rise of potential V_{G} of a gate conductive part 44 is delayed compared to those in the semiconductor apparatus 200 and the semiconductor apparatus 300. Moreover, switching-on start timing corresponding to timing when emitter-collector voltage V_{C} starts to drop is also delayed.

That is, in the semiconductor apparatus 100, the potential V_{G} of the gate conductive part 44 rises more quickly and the switching-on start timing is earlier than that in the semiconductor apparatus 400 where the emitter non-contact trench part 130 is provided without providing a diode 110, and a switching-on power loss can be smaller than that in the semiconductor apparatus 300.

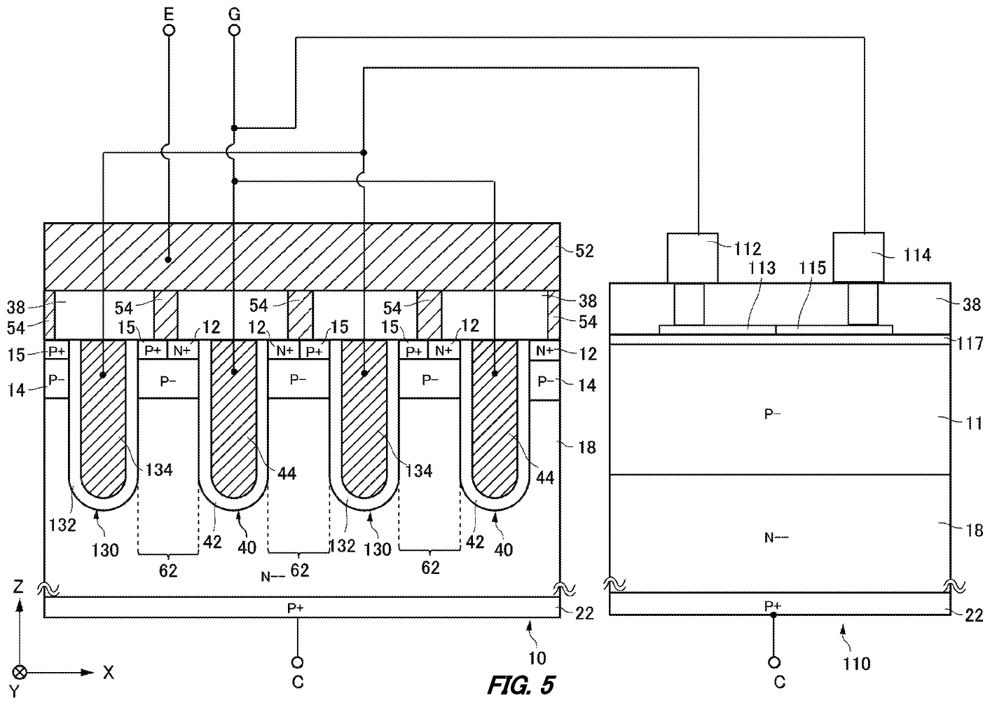

FIG. 5 shows another example of the cross-sectional view of the semiconductor apparatus 100. The diode 110 may be a float diode formed on the same chip as the semiconductor apparatus 100 and having a PN junction of the diode 110 formed above an oxide film 117.

The diode 110 includes a second conductivity type well region 11 provided above the drift region 18, the oxide film 117 covering the upper surface of the well region 11, and an N type cathode diffusion region 113 and a P type anode diffusion region 115 that are formed above the oxide film. The cathode diffusion region 113 may be connected to the cathode electrode 112 via a contact hole or the like, and the anode diffusion region 115 may be connected to an anode electrode 114 via a contact hole or the like. In this example, the anode diffusion region 115 and the anode electrode 114 constitute an anode of the diode 110, and the cathode diffusion region 113 and the cathode electrode 112 constitute a cathode of the diode 110.

The oxide film 117 has thickness equal to or greater than a predetermined threshold value. Giving thickness to the oxide film 117 can reduce parasitic capacitance between the cathode diffusion region 113 and the anode diffusion region 115, and the well region 11. Moreover, providing a thick oxide film can suppress generation of leak current from the well region 11.

As an example, the oxide film 117 may be a LOCOS oxide film provided by forming a recess on the semiconductor substrate 10. Making the oxide film 117 a LOCOS oxide film can facilitate giving thickness to the oxide film 117 and can flatten its surface, so that flexibility in design can be improved.

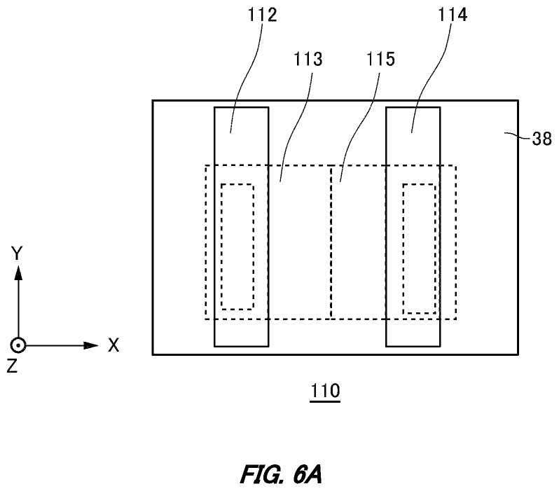

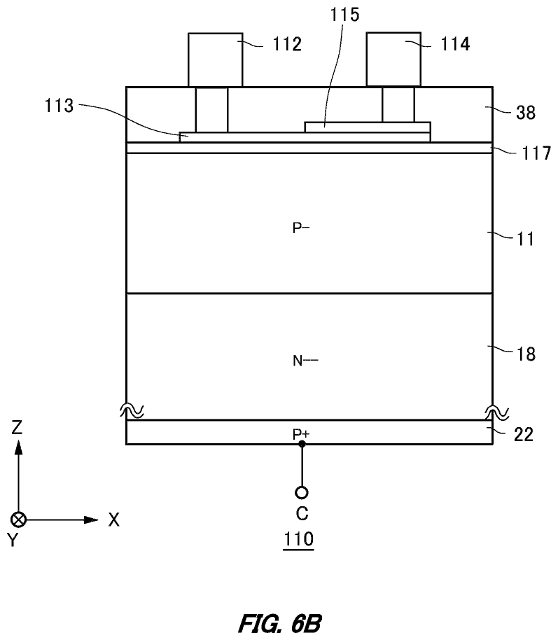

FIG. 6A shows an example of a top view of the diode 110. The diode 110 includes a PN junction portion embedded in an interlayer dielectric film 38. A PN junction is formed between the cathode diffusion region 113 and the anode diffusion region 115.

FIG. 6B shows another example of a cross-sectional view of the diode 110. In this example, the anode diffusion region 115 is formed above the cathode diffusion region 113. That is, the PN junction of the diode 110 is joined in the vertical direction.

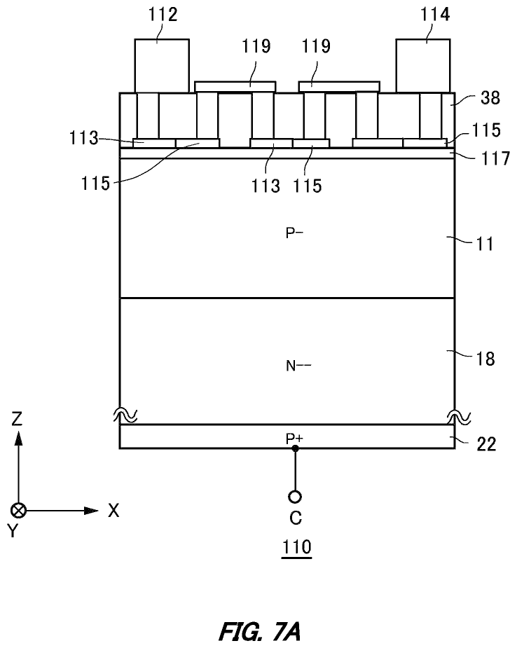

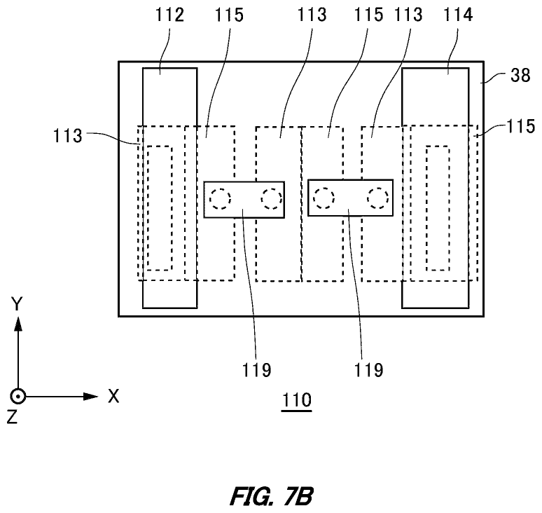

FIG. 7A shows yet another example of the cross-sectional view of the diode 110. The diode 110 in this example includes three cathode diffusion regions 113 and three anode diffusion regions 115.

In this example, from the negative side in the X axis direction to the positive side in the X axis direction, the anode diffusion region 115 provided in the first position and the cathode diffusion region 113 provided in the second position are electrically connected via a contact hole or the like and a connection part 119 or the like. Likewise, from the negative side in the X axis direction to the positive side in the X axis direction, the anode diffusion region 115 provided in the second position and the cathode diffusion region 113 provided in the third position are electrically connected via the connection part 119.

In this example, shown is an example of a three-stage diode 110 where the number of PN junctions is three, but the number of stages is not limited to three. Depending on a desired capacitance provided to the emitter non-contact trench part 130, the number of stages may be two, or may be increased to even more.

FIG. 7B shows another example of the top view of the diode 110. This example is an example in planar view of the diode 110 in FIG. 7A.

As in this example, the connection part 119 may be provided so as to be narrower than the cathode diffusion region 113 and the anode diffusion region 115. On the contrary, it may be provided so as to be wider than the cathode diffusion region 113 and the anode diffusion region 115.

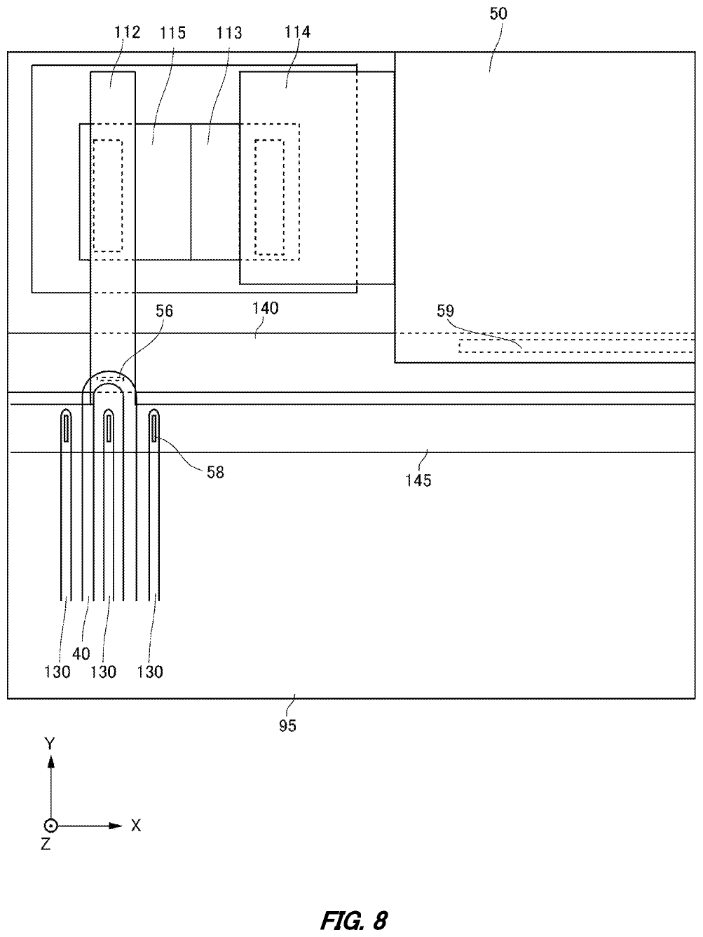

FIG. 8 shows an example of an enlarged view of the upper surface of the semiconductor apparatus 100. This example is an example of an enlarged view of a region B in FIG. 1A.

In this example, the diode 110 is provided adjacent to the gate pad 50. The anode electrode 114 of the diode 110 in this example is electrically connected to the gate pad 50. On the other hand, the cathode electrode 112 of the diode 110 in this example is extended to the active region 95, and is electrically connected to the gate metal layer 145.

The diode 110 may be a Zener diode. The diode 110 can be designed as a Zener diode by increasing doping concentrations of the anode diffusion region 115 and the cathode diffusion region 113 of the diode 110. The Zener diode can provide a better rectification characteristic for reverse current.

The gate runner 140 is provided so as to overlap the gate pad 50. The gate runner 140 is electrically connected to the gate pad 50 through a contact hole 59, and is set to the gate potential V_{g}.

The gate trench part 40 is provided so as to overlap the gate runner 140 in planar view. The gate trench part 40 is electrically connected to the gate runner 140 through a contact hole 56. The gate conductive part 44 of the gate trench part 40 is set to the gate potential V_{g}.

The emitter non-contact trench part 130 is provided so as to overlap the gate metal layer 145 in planar view. The emitter non-contact trench part is electrically connected to the gate metal layer 145 through a contact hole 58. The emitter non-contact trench conductive part 134 of the emitter non-contact trench part 130 is set to the gate potential V_{g}. That is, the emitter non-contact trench part 130 is connected to the gate pad 50 via the diode 110.

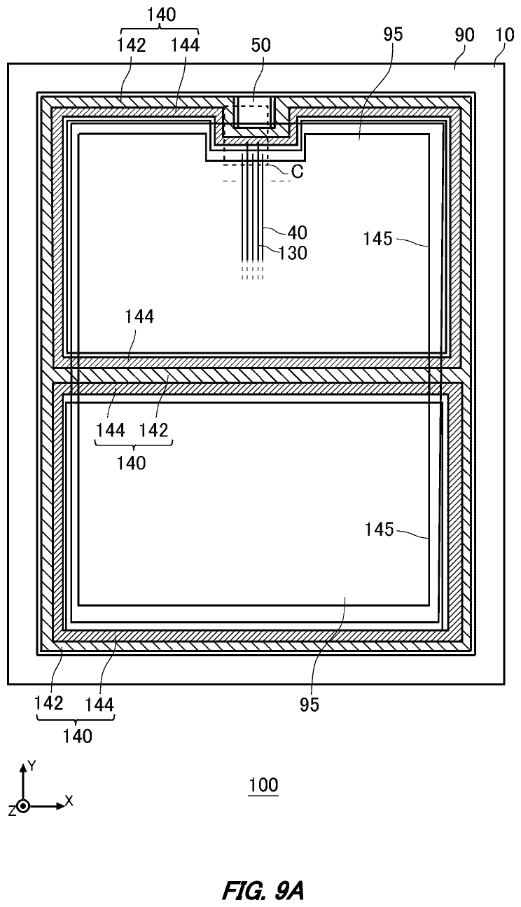

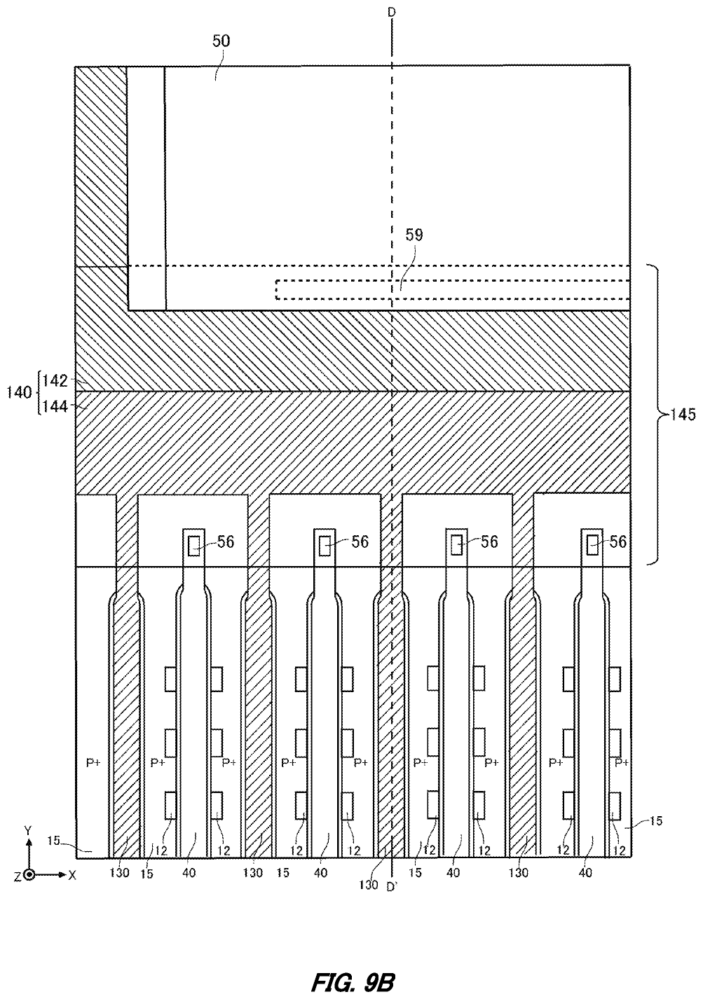

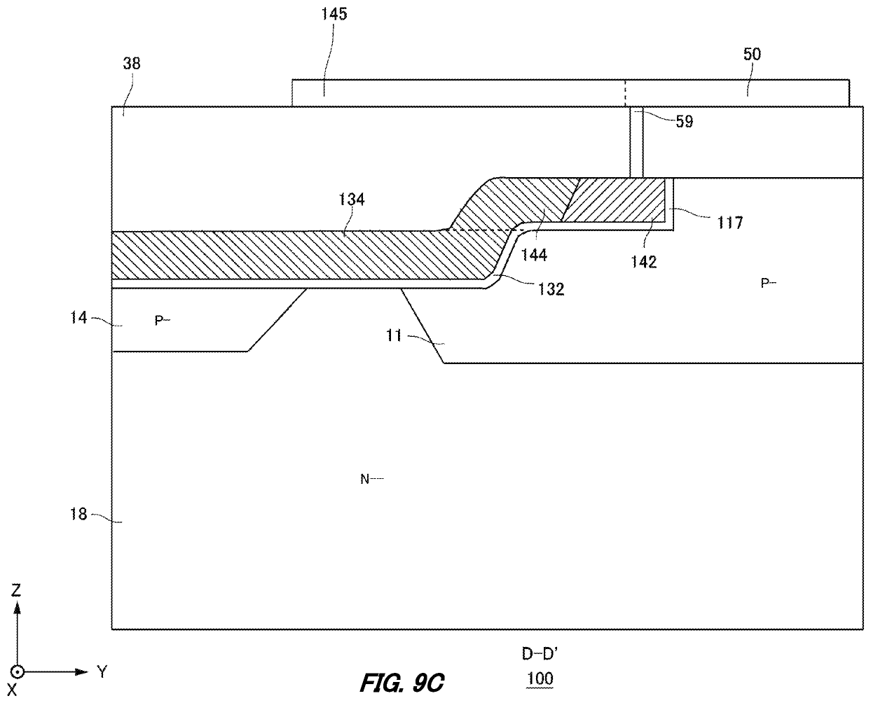

FIG. 9A shows another example of the top view of the semiconductor apparatus 100. In this example, the gate runner 140 includes two layers: an outer peripheral gate runner 142 and an inner peripheral gate runner 144. Moreover, the gate pad 50 is connected to the gate metal layer 145.

The outer peripheral gate runner 142 is electrically connected to the gate pad 50. As an example, the outer peripheral gate runner 142 is formed of a P type semiconductor. The outer peripheral gate runner 142 is an example of an anode peripheral region.

As an example, the inner peripheral gate runner 144 is formed of an N type semiconductor. The inner peripheral gate runner 144 is an example of a cathode peripheral region. That is, in this example, a PN junction is formed between the outer peripheral gate runner 142 and the inner peripheral gate runner 144 in the gate runner 140. In this case, the diode 110 is provided in the gate runner 140, an anode of the diode 110 includes the outer peripheral gate runner 142, and a cathode of the diode 110 includes the inner peripheral gate runner 144.

The emitter non-contact trench part 130 is electrically connected to the inner peripheral gate runner 140. That is, the emitter non-contact trench part 130 is electrically connected to the gate pad 50 via the diode 110.

The gate trench part 40 is electrically connected to the gate metal layer 145. That is, the gate trench part 40 is electrically connected to the gate pad 50 via the gate metal layer 145.

FIG. 9B shows another example of the enlarged view of the upper surface of the semiconductor apparatus 100. This example is an example of an enlarged view of a region C in FIG. 9A.

The outer peripheral gate runner 142 is electrically connected to the gate pad 50 and the gate metal layer 145 via the contact hole 59. The gate runner 140 and the gate metal layer 145 is set to the gate potential V_{g}.

The inner peripheral gate runner 144 forms a PN junction with the outer peripheral gate runner 142. The inner peripheral gate runner 144 in this example is formed of N type polysilicon, and the inner peripheral gate runner 144 is integrally formed with at least one emitter non-contact trench conductive part 134 of a plurality of emitter non-contact trench parts 130. That is, the emitter non-contact trench conductive part 134 in this example is formed of N type polysilicon.

FIG. 9C shows an example of a cross-sectional view in an extending direction of a trench part of the semiconductor apparatus 100. In this example, the emitter non-contact trench conductive part 134 of the emitter non-contact trench part 130 and the inner peripheral gate runner 144 of the diode 110 are integrally formed.

The emitter non-contact trench conductive part 134 rides on the upper part of the oxide film 117, and goes around the periphery of the active region 95 as the inner peripheral gate runner 144. Further, the outer peripheral gate runner 142 going around outside the inner peripheral gate runner 144 constitutes a PN junction with the inner peripheral gate runner 144.

The interlayer dielectric film 38 covers the upper parts of the outer peripheral gate runner 142, the inner peripheral gate runner 144, and the emitter non-contact trench part 130. The contact hole 59 is provided inside the interlayer dielectric film 38 above the outer peripheral gate runner 142, and electrically connects the gate pad 50, the gate metal layer 145, and the outer peripheral gate runner 142.

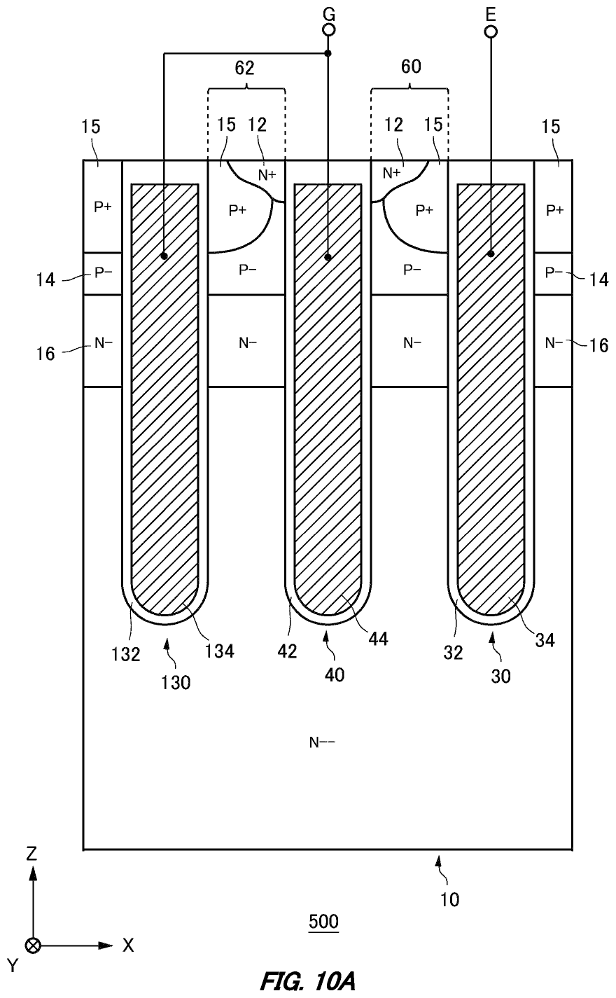

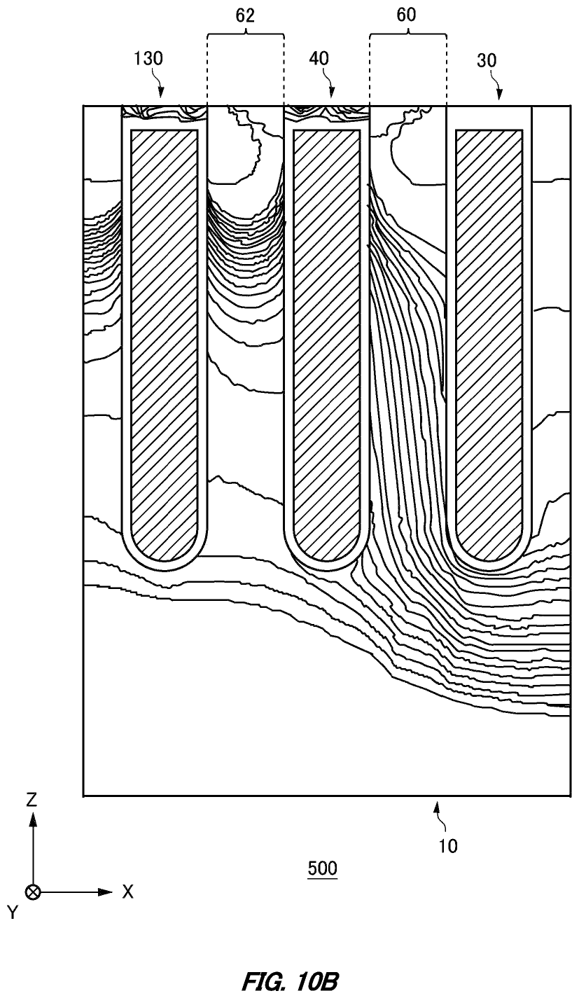

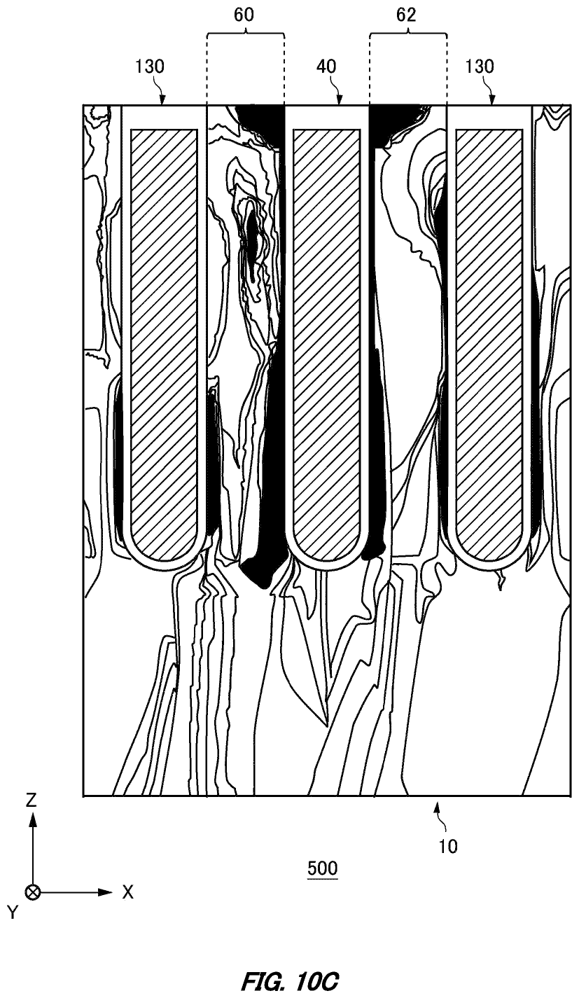

FIG. 10A shows an example of a cross-sectional view of a semiconductor apparatus 500. The semiconductor apparatus 500 includes three trench parts. The semiconductor apparatus 500 in this example includes, from the negative side to the positive side in the X axis direction, an emitter non-contact trench part 130, a gate trench part 40, and a dummy trench part 30.

FIG. 10B shows an example of a diagram of equipotential lines in the cross-sectional view of the semiconductor apparatus 500. In this example, shown is an example where, when the semiconductor apparatus 500 is an IGBT device, gate resistance is 5Ω), gate voltage is 12.7 [V], and emitter-collector voltage is 409 [V].

In the emitter non-contact trench part 130, as potential of a gate conductive part of the gate trench part 40 is increased, voltage of the emitter non-contact trench conductive part 134 is also increased. Therefore, equipotential lines in a mesa part 62 are extended between the emitter non-contact trench part 130 and the gate trench part 40. While the potential of the gate conductive part is increased, the equipotential lines remain extended between the trenches, and potential of the mesa part 62 is increased.

On the other hand, a dummy conductive part 34 of the dummy trench part 30 has emitter potential Vₑ. For example, when V_{E} is ground potential, even if the potential of the gate conductive part 44 of the gate trench part 40 is increased, the emitter potential Vₑ does not change from the ground potential before and after the increase.

Therefore, in a mesa part 60 between the dummy trench part 30 and the gate trench part 40, equipotential lines are extended in a direction substantially parallel to the depth direction of the semiconductor apparatus 500. In the vicinity of the dummy trench part 30, the emitter potential Vₑ is fixed near the ground potential from the front surface of the semiconductor substrate 10 to the bottom of the dummy trench part 30. Therefore, in the mesa part 60, a lateral electric field is generated, and potential increase becomes slow. This causes a delay of turn-on end time in the mesa part 60 around the dummy trench part 30.

FIG. 10C shows an example of a contour diagram of a current value in the cross-sectional view of the semiconductor apparatus 500. In this example again, shown is an example where, when the semiconductor apparatus 500 is an IGBT device, gate resistance is 5Ω), gate voltage is 12.7 [V], and emitter-collector voltage is 409 [V]. In the figure, a range where the current value has a value equal to or greater than a certain threshold value is filled in black.

In the mesa part 62 between the emitter non-contact trench part 130 and the gate trench part 40, as the potential is increased, the current value is also increased spreading to the mesa part 62. In the mesa part 62, the current is also increased spreading entirely inside the mesa part 62.

On the other hand, in a second mesa part 60 of the dummy trench part 30 and the gate trench part 40, a region where current flows is concentrated in the vicinity of the gate trench part 40 where a channel is formed in a base region 14. Therefore, the current flowing through the mesa part 60 is more likely to cause current concentration than the current flowing through the mesa part 62, and the biased current not only destabilizes switching-on operation but also increases switching-on power loss.

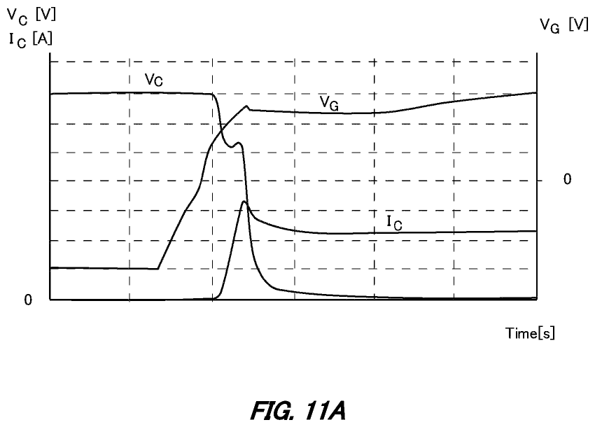

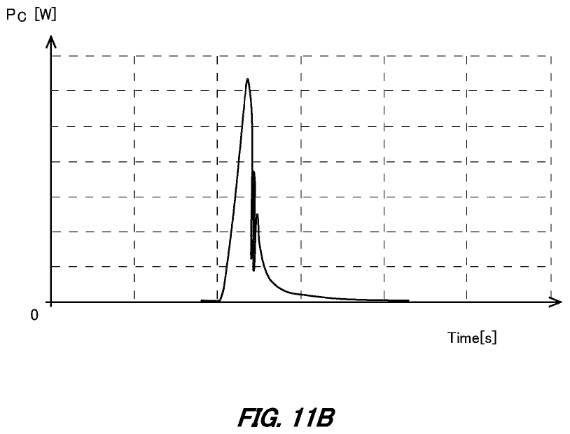

FIGS. 11A to 13B show graphs at the time of turn-on operation when gate input waveforms are the same.

FIG. 11A shows an example of current and voltage waveforms at the time of switching of the semiconductor apparatus 500. In this example, shown is a graph where, when the semiconductor apparatus 500 is an IGBT device, gate resistance is set to 1×RG [Ω], wherein the RG [Ω] is an arbitrary resistance value.

Emitter-collector voltage V_{C}, emitter-collector current I_{C}, and potential V_{G} of the gate conductive part 44 are shown. In this example, the emitter-collector voltage V_{C} is sharply reduced, and the emitter-collector current I_{C} also sharply rises. Since a power loss P_{C} per unit time at the time of switching is given by a product of the V_{C} and the I_{C}, it contributes greatly to an amount of change in the absolute value of the P_{C}.

FIG. 11B shows an example of a graph of a power loss per unit time at the time of switching of the semiconductor apparatus 500. The larger an area surrounded by a straight line of P_{C}=0 [W] and a curve drawn by the P_{C} is, the greater a value of the power loss is.

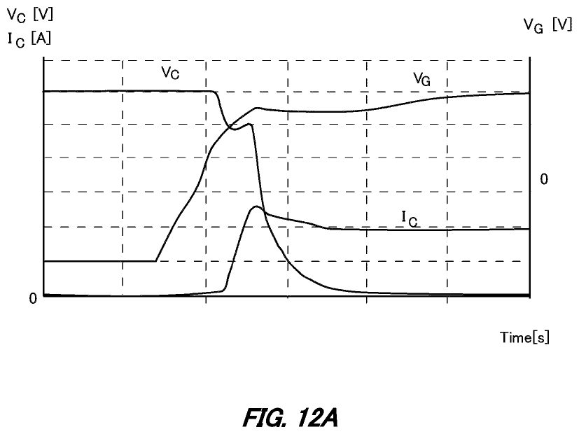

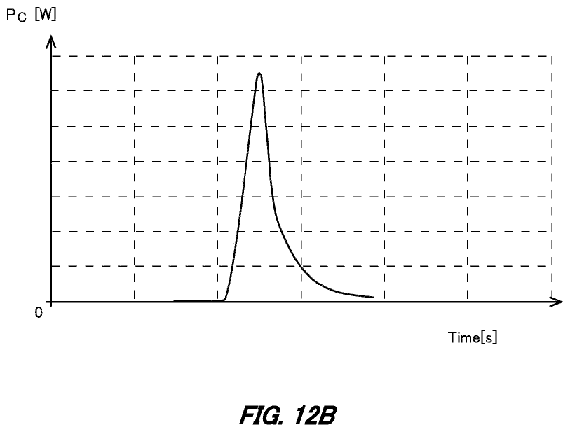

FIG. 12A shows another example of the current and voltage waveforms at the time of switching of the semiconductor apparatus 300. In this example, shown is a graph, where, when the semiconductor apparatus 300 is an IGBT device, gate resistance is set to 1×RG [Ω], wherein the RG [Ω] shown in FIG. 12A is the same resistance value as the RG [Ω] shown in FIG. 11A.

In this example, emitter-collector voltage V_{C} is sharply reduced, but as it approaches a value of 0V, it gets gently reduced and time required for the turn-on operation becomes longer. This is because the mesa part between the gate trench part 40 and the dummy trench part 30 has a lateral electric field, and the dummy conductive part 34 of the dummy trench part 30 has the emitter potential Vₑ, so that operation of lowering potential of the entire mesa part becomes slow.

Moreover, in this example, turn-on start timing is early, emitter-collector current I_{C} is operating current, and the emitter-collector current I_{C} is also large. Therefore, a power loss P_{C} per unit time at the time of turn-on is larger.

FIG. 12B shows an example of a graph of a power loss per unit time at the time of switching of the semiconductor apparatus 300. In this example, since the emitter-collector voltage V_{C} is more gently decreased than that in the example of the semiconductor apparatus 500, a value of the P_{C} is more slowly decreased and switching time is longer. Therefore, an integrated value over time of the P_{C} is also greater than that in the example of the semiconductor apparatus 500.

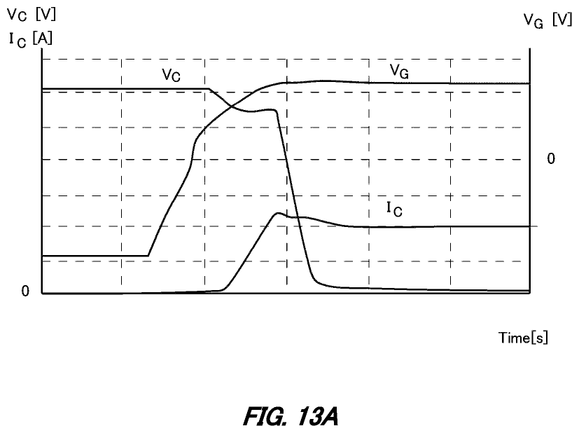

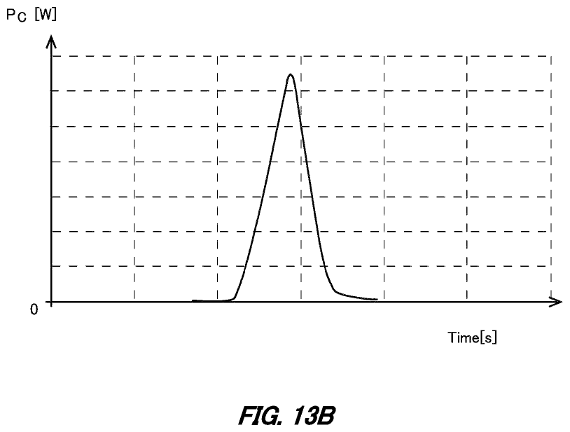

FIG. 13A shows another example of the current and voltage waveforms at the time of switching of the semiconductor apparatus 200. In this example, shown is a graph where, when the semiconductor apparatus 300 is an IGBT device, gate resistance is set to 1×RG [Ω], wherein the RG [Ω] shown in FIG. 13A is the same resistance value as the RGs [Ω] shown in FIGS. 11A and 12A.

In this example, the V_{C} is stably and linearly reduced to complete the switching-on operation. Since the V_{C} is slowly decreased, switching time is increased, and a power loss P_{C} at the time of turn-on is larger. However, the maximum value of dV/dt can be significantly reduced.

FIG. 13B shows an example of a graph of power loss per unit time at the time of switching of the semiconductor apparatus 200. In the graph of FIG. 13B, an integrated value over time of the absolute value of the P_{C} is greater than that in the example of the semiconductor apparatus 300.

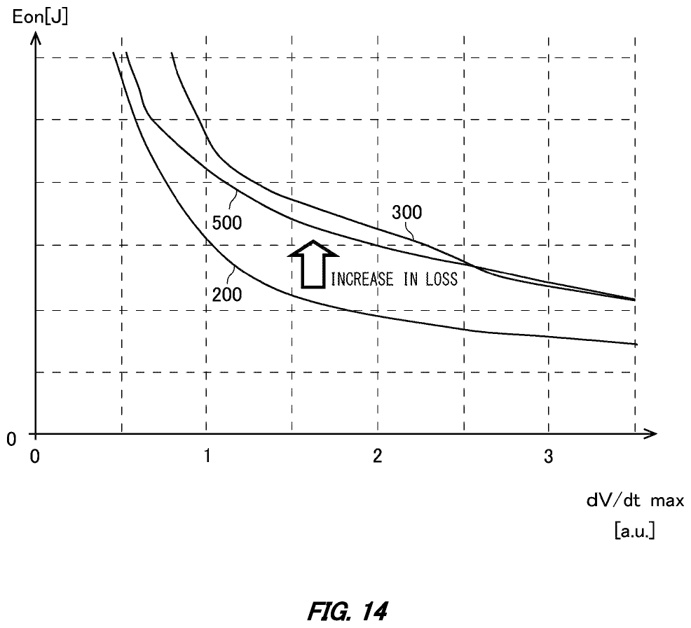

FIG. 14 shows an example of a graph of switching losses of the semiconductor apparatus 200, the semiconductor apparatus 300, and the semiconductor apparatus 500. In this example, shown is a graph where the horizontal axis represents the maximum value of dV/dt [a.u.] (arbitrary unit) and the vertical axis represents an on-state power loss Eon [J] at the time of switching.

The semiconductor apparatus 200 includes the gate trench part 40 and the emitter non-contact trench part 130. That is, a ratio of the dummy trench part 30 and the emitter non-contact trench part 130 included in the semiconductor apparatus 200 is 0:1. The semiconductor apparatus 300 includes the dummy trench part 30 and the emitter non-contact trench part 130 at a ratio of 1:0. The semiconductor apparatus 500 includes the dummy trench part 30 and the emitter non-contact trench part 130 at a ratio of 1:1. Magnitudes of the switching losses of the semiconductor apparatus 300 and the semiconductor apparatus 500 are larger than that of the semiconductor apparatus 200. In particular, this is noticeable on the side where dV/dt [a.u.] is higher.

In the mesa part 60 between the dummy trench part 30 and the gate trench part 40, operating waveform is steep and turn-on end time is delayed. Therefore, when the emitter non-contact trench part 130 and the dummy trench part 30 coexist, the higher a ratio of a dummy gate is, the larger a turn-on power loss is. As an example the semiconductor apparatus 100 includes the gate trench part 40 and the emitter non-contact trench part 130 at a ratio of 1:1, and includes no dummy trench part 30. When the semiconductor apparatus 100 includes all of the gate trench part 40, the emitter non-contact trench part 130, and the dummy trench part 30, it includes the dummy trench part 30 and the emitter non-contact trench part 130 at a ratio of x:1, where x may be a value smaller than 1.

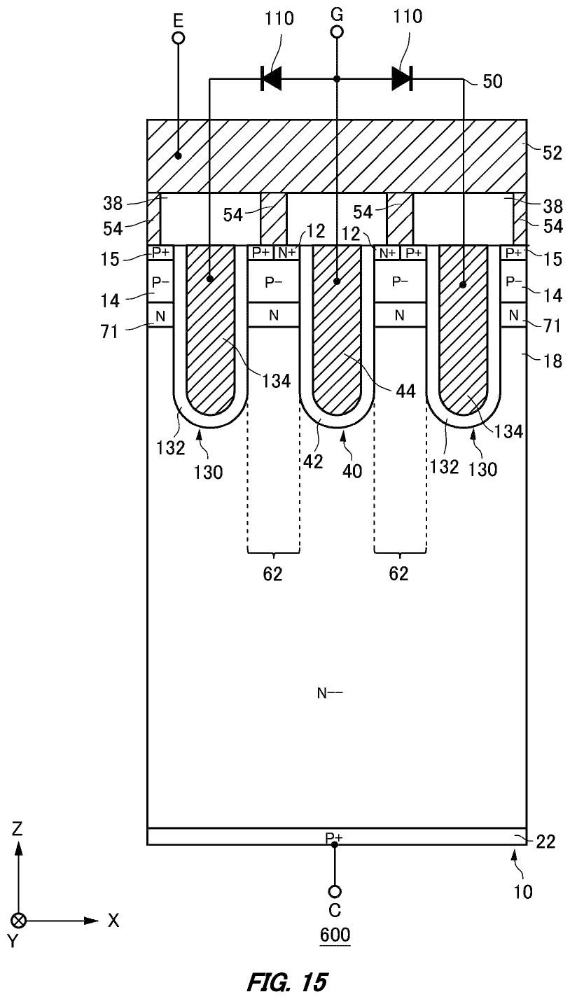

FIG. 15 shows an example of a cross-sectional view of a semiconductor apparatus 600 according to a comparative example. The semiconductor apparatus 600 includes an N type storage region 71 between an N− type drift region 18 and a P− type base region 14 provided above the drift region 18. The storage region 71 has a doping concentration higher than that of the drift region 18.

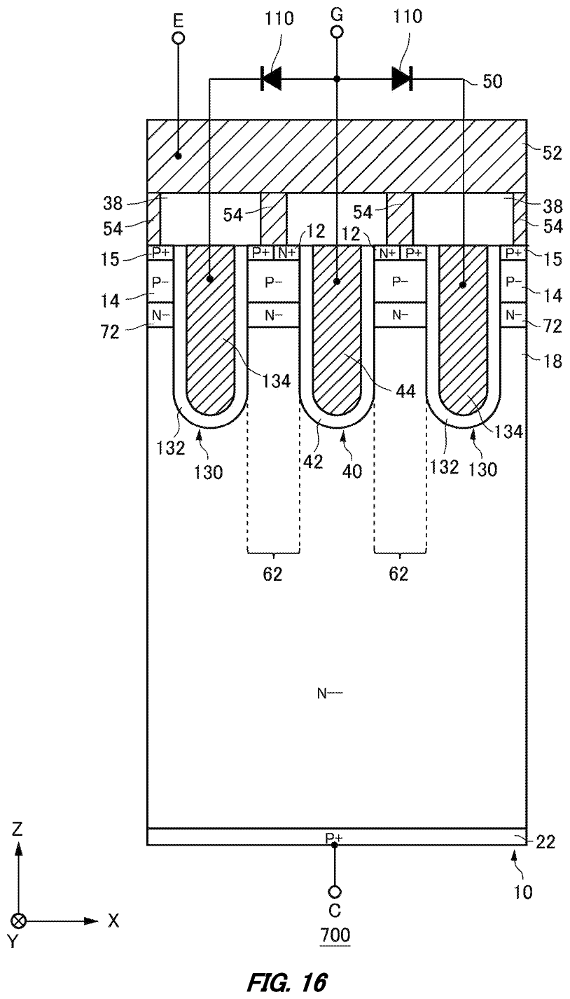

FIG. 16 shows an example of a cross-sectional view of a semiconductor apparatus 700 according to a comparative example. The semiconductor apparatus 700 includes an N− type storage region 72 between an N− type drift region 18 and a P− type base region 14 provided above the drift region 18. The storage region 72 has a doping concentration higher than that of the drift region 18.

The semiconductor apparatus 700 in this example is different from the semiconductor apparatus 500 in that it includes the storage region 72 having a doping concentration different from that of the storage region 71. The storage region 72 has a doping concentration lower than that of the storage region 71.

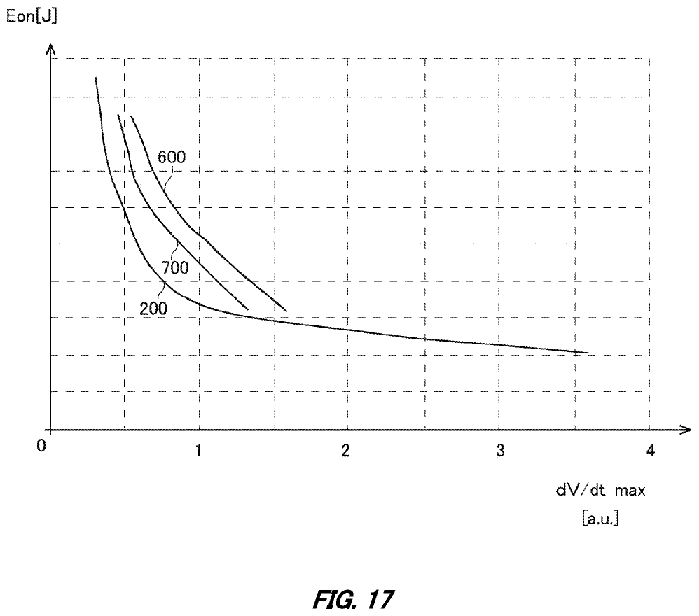

FIG. 17 shows an example of a graph of switching losses of the semiconductor apparatus 200, the semiconductor apparatus 600, and the semiconductor apparatus 700. In this example, shown is a graph where the horizontal axis represents the maximum value of dV/dt [a.u.] and the vertical axis represents an on-state power loss Eon [J] at the time of switching. This example shows a graph at room temperature RT (25 degrees C.).

The semiconductor apparatus 200 is the semiconductor apparatus 200 shown in FIG. 2B, and includes no N type storage region. The semiconductor apparatus 600 is the semiconductor apparatus 600 shown in FIG. 15. Moreover, the semiconductor apparatus 700 is the semiconductor apparatus 700 shown in FIG. 16. The semiconductor apparatus 600 and the semiconductor apparatus 700 include respectively the storage region 71 and the storage region 72 having different doping concentrations.

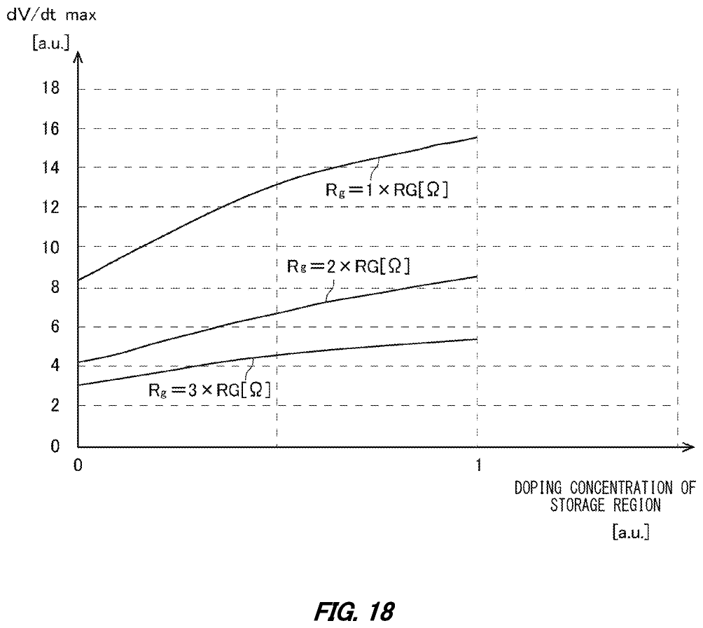

FIG. 18 shows an example of a graph of a doping concentration of a storage region and a switching loss. In this example, shown is a graph where the horizontal axis represents the doping concentration [a.u.] of the storage region, the vertical axis represents the maximum value of dV/dt [a.u.], and gate resistance R_{g} is 1×RG [Ω], 2× RG [Ω], or 3× RG [Ω].

As the doping concentration [a.u.] of the storage region becomes higher, the maximum value of dV/dt [a.u.] is increased. Moreover, as the gate resistance R_{g} is lower, the maximum value of dV/dt [a.u.] is significantly increased.

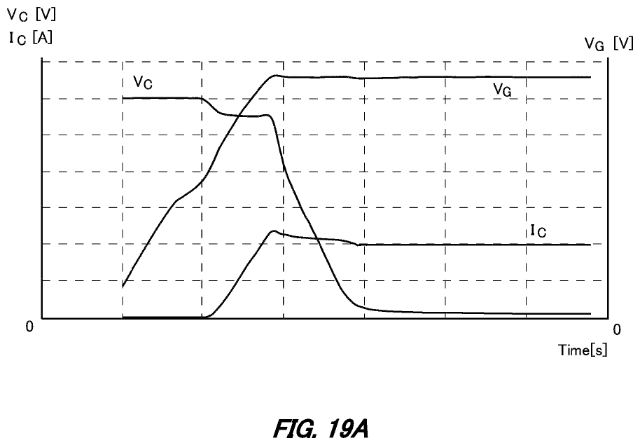

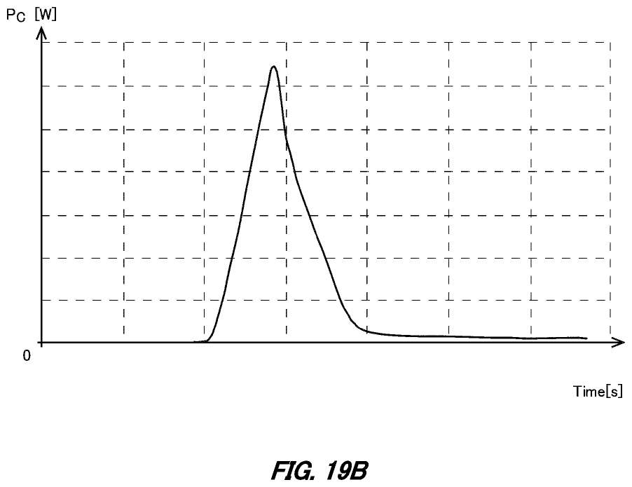

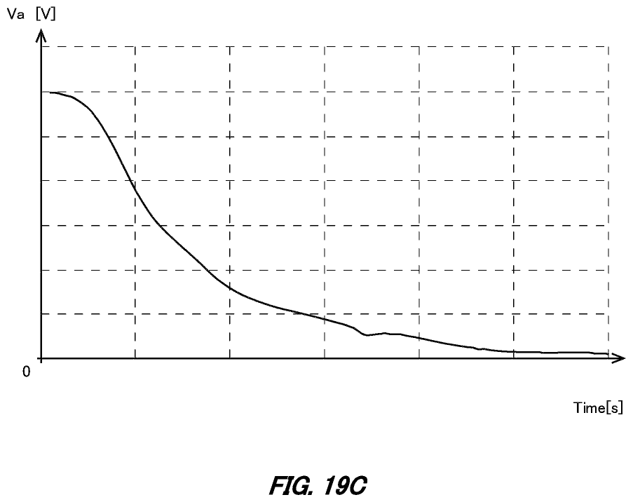

FIG. 19A shows an example of current and voltage waveforms at the time of switching of the semiconductor apparatus 600 or the semiconductor apparatus 700. Emitter-collector voltage V_{C}, emitter-collector current I_{C}, and potential V_{G} of the gate conductive part 44 are shown. In this example, shown is a graph where, when the semiconductor apparatus 600 or the semiconductor apparatus 700 is an IGBT device including respectively the storage region 71 or the storage region 72, gate resistance is set to 2×RG [Ω], wherein the RG [Ω] is an arbitrary resistance value.

FIG. 19B shows an example of a graph of an on-state power loss P_{C} [W] per unit time at the time of switching of the semiconductor apparatus 600 or the semiconductor apparatus 700. In this example, shown is a graph where, when the semiconductor apparatus 600 or the semiconductor apparatus 700 is an IGBT device including respectively the storage region 71 or the storage region 72, gate resistance is set to 2× RG [Ω], wherein the RG [Ω] is the same value as the resistance value RG [Ω] in FIG. 19A.

FIG. 19C shows a reverse recovery characteristic (diode anode voltage Va [V]) of the diode 110 at the time of switching of the semiconductor apparatus 600 or the semiconductor apparatus 700. In this example, shown is a graph where, when the diode 110 connected to the semiconductor apparatus 600 or the semiconductor apparatus 700 is an FWD (Free Wheeling Diode) device, gate resistance is set to 2×RG [Ω], wherein the RG [Ω] is the same value as the resistance value RG [Ω] in FIG. 19A.

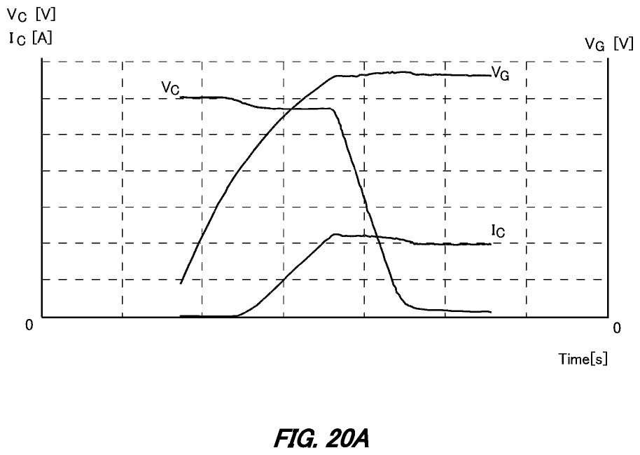

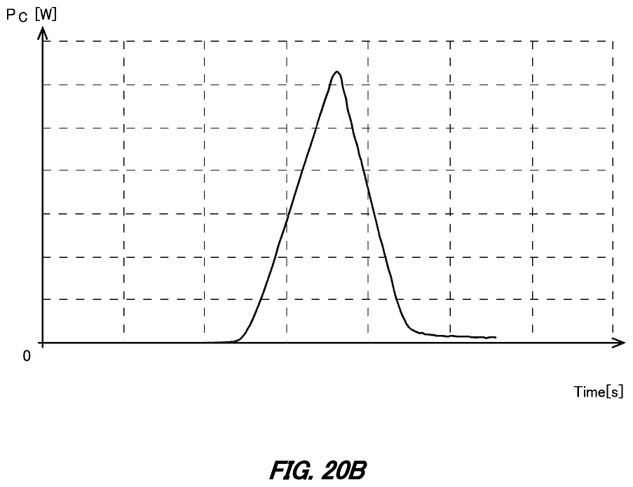

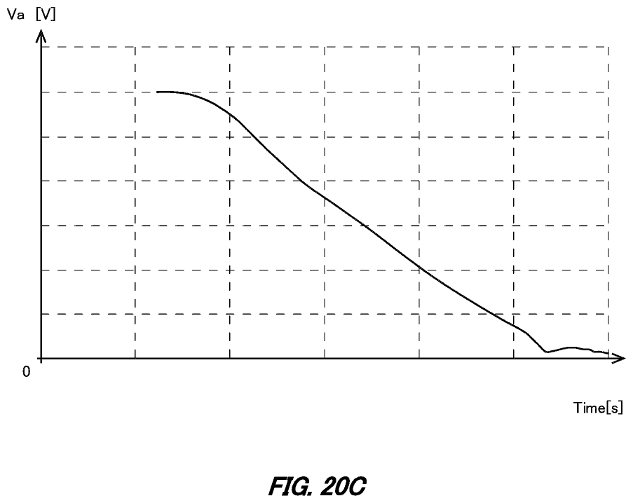

FIG. 20A shows another example of the current and voltage waveforms at the time of switching of the semiconductor apparatus 200. Emitter-collector voltage V_{C}, emitter-collector current I_{C}, and potential V_{G} of the gate conductive part 44 are shown. In this example, shown is a graph where, when the semiconductor apparatus 200 is an IGBT device including no storage region, gate resistance is set to 2×RG [Ω], wherein the RG [Ω] is an arbitrary resistance value, and is the same value as the resistance value RG [Ω] shown in FIG. 19A.

FIG. 20B shows an example of a graph of an on-state power loss P_{C} [W] per unit time at the time of switching of the semiconductor apparatus 200. In this example, shown is a graph where, when the semiconductor apparatus 200 is an IGBT device including no storage region, gate resistance is set to 2×RG [Ω], wherein the RG [Ω] is the resistance value in FIG. 20A.

FIG. 20C shows a reverse recovery characteristic (diode anode voltage Va [V]) of the diode 110 at the time of switching of the semiconductor apparatus 200. In this example, shown is a graph where, when the diode 110 connected to the semiconductor apparatus 200 is an FWD device, gate resistance is set to 2×RG [Ω], wherein the RG [Ω] is the same value as the resistance value RG [Ω] in FIG. 20A.

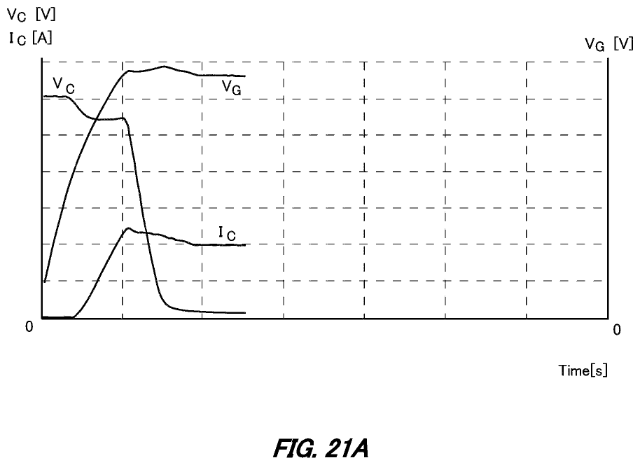

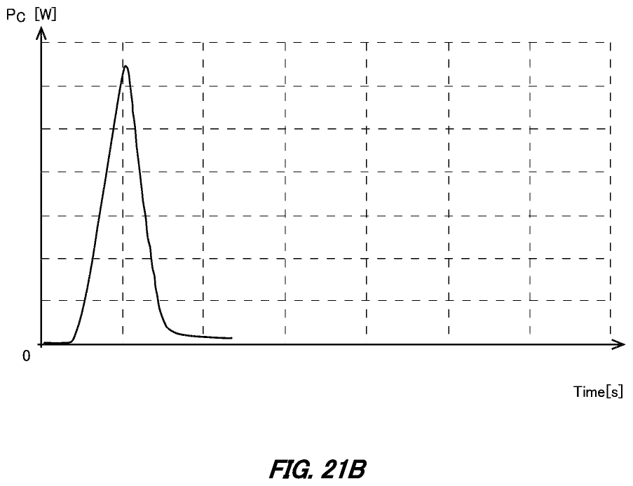

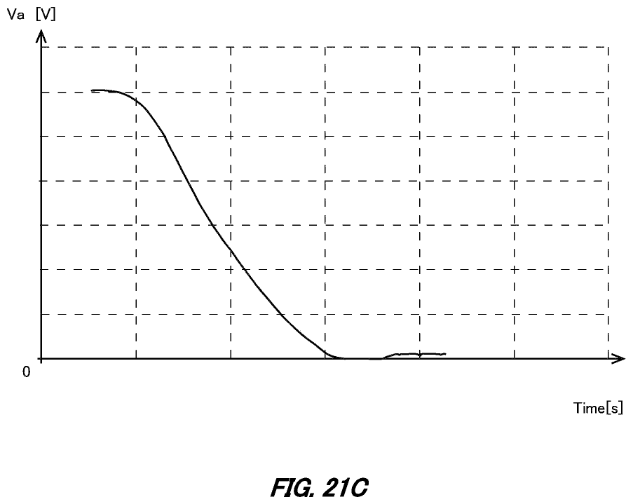

FIG. 21A shows another example of the current and voltage waveforms at the time of switching of the semiconductor apparatus 200. Emitter-collector voltage V_{C}, emitter-collector current I_{C}, and potential V_{G} of the gate conductive part 44 are shown. In this example, shown is a graph where, when the semiconductor apparatus 200 is an IGBT device including no storage region, gate resistance is set to 1×RG [Ω], wherein the RG [Ω] is an arbitrary resistance value, and is the same value as the resistance value RG [Ω] shown in FIG. 19A.

FIG. 21B shows another example of the graph of the on-state power loss P_{C} [W] per unit time at the time of switching of the semiconductor apparatus 200. In this example, shown is a graph where, when the semiconductor apparatus 200 is an IGBT device including no storage region, gate resistance is set to 1×RG [Ω], wherein the RG [Ω] is the resistance value in FIG. 21A.

FIG. 21C shows the reverse recovery characteristic (diode anode voltage Va [V]) of the diode 110 at the time of switching of the semiconductor apparatus 200. In this example, shown is a graph where, when the diode 110 connected to the semiconductor apparatus 200 is an FWD device, gate resistance is set to 1×RG [Ω], wherein the RG [Ω] is the same value as the resistance value RG [Ω] in FIG. 21A.

As shown above, the gate resistance of the semiconductor apparatus in FIGS. 20A to 20C is 2×RG [Ω], and the gate resistance of the semiconductor apparatus in FIGS. 21A to 21C is 1×RG [Ω]. That is, the semiconductor apparatus in FIGS. 20A to 20C and the semiconductor apparatus in FIGS. 21A to 21C are different in their values of gate resistance R_{g}.

In FIGS. 19A and 20A, the semiconductor apparatus 600 including the storage region 71 or the semiconductor apparatus 700 including the storage region 72 has a switching speed higher than that of the semiconductor apparatus 200 including no storage region. Moreover, in FIGS. 19B and 20B, the semiconductor apparatus 600 including the storage region 71 or the semiconductor apparatus 700 including the storage region 72 has an on-state power loss Eon [J] smaller than that of the semiconductor apparatus 200 including no storage region.

For the on-state power loss Eon [J] at the time of turn-on of the IGBT device, the larger an area surrounded by a straight line of P_{C}=0 [W] and a curve drawn by the P_{C} [W], which is shown in each of FIGS. 19B and 20B, is, the greater a value of the on-state power loss is. FIGS. 19B and 20B, where the gate resistances R_{g} are the same, have these areas almost the same.

Reverse recovery characteristics will be compared below for a case where the diodes 110 shown in FIGS. 19C and 20C are an FWD device.

In FIG. 19C where the storage region 71 or the storage region 72 is included, the storage region 71 or the storage region 72, and the drift region 18 are in serial contact with each other, and resistance of this portion is reduced. This accelerates a voltage drop immediately after the IGBT device is turned on, and increases the maximum value of dV/dt [a.u.].

In FIG. 20C where no storage region is included, the voltage drop immediately after the IGBT device is turned on becomes gentle, and the maximum value of dV/dt [a.u.] is not increased. Therefore, without storage region included, the increase in the maximum value of dV/dt [a.u.] at the time of turn-on of the IGBT device is suppressed, and the on-state power loss Eon [J] is improved.

In order to obtain the same maximum value of dV/dt [a.u.] as when there is a storage region, when there is no storage region, the gate resistance R_{g} may be lowered as shown in FIG. 21C. Lowering the gate resistance R_{g} shortens switching time as shown in FIG. 21A, and can reduce the on-state power loss Eon [J] as shown in FIG. 21B.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

10: semiconductor substrate, 11: well region, 12: emitter region, 14: base region, 15: contact region, 18: drift region, 22: collector region, 30: dummy trench part, 32: dummy dielectric film, 34: dummy conductive part, 38: interlayer dielectric film, 40: gate trench part, 42: gate dielectric film, 44: gate conductive part, 50: gate pad, 52: emitter electrode, 54: contact hole, 56: contact hole, 58: contact hole, 59: contact hole, 60: mesa part, 62: mesa part, 71: storage region, 72: storage region, 90: edge termination structure part, 95: active region, 100: semiconductor apparatus, 110: diode, 112: cathode electrode, 113: cathode diffusion region, 114: anode electrode, 115: anode diffusion region, 117: oxide film, 119: connection part, 130: emitter non-contact trench part, 132: emitter non-contact trench dielectric film, 134: emitter non-contact trench conductive part, 140: gate runner, 142: outer peripheral gate runner, 144: inner peripheral gate runner, 145: gate metal layer, 200: semiconductor apparatus, 300: semiconductor apparatus, 400: semiconductor apparatus, 500: semiconductor apparatus, 600: semiconductor apparatus, 700: semiconductor apparatus

What is claimed is:

1. A semiconductor apparatus comprising:
an emitter region having a first conductivity type provided on a front surface of a semiconductor substrate;
a first gate trench part and a second gate trench part in contact with the emitter region;
a first emitter non-contact trench part and a second emitter non-contact trench part out of contact with the emitter region;
a gate pad for setting the first gate trench part, the second gate trench part, the first emitter non-contact trench part, and the second emitter non-contact trench part to gate potential; and
a diode having an anode connected to the gate pad and a cathode connected to the first emitter non-contact trench part and the second emitter non-contact trench part, wherein
the first gate trench part, the first emitter non-contact trench part, the second gate trench part, and the second emitter non-contact trench part are adjacently arranged in order.

2. The semiconductor apparatus according to claim 1, wherein on the front surface of the semiconductor substrate, the emitter region is extended from the first gate trench part to a direction of the first emitter non-contact trench part, and is terminated without reaching the first emitter non-contact trench part.

3. The semiconductor apparatus according to claim 1, wherein on the front surface of the semiconductor substrate, the emitter region is extended from the second gate trench part to a direction of the first emitter non-contact trench part, and is terminated without reaching the first emitter non-contact trench part.

4. The semiconductor apparatus according to claim 2, wherein on the front surface of the semiconductor substrate, the emitter region is extended from the second gate trench part to the direction of the first emitter non-contact trench part, and is terminated without reaching the first emitter non-contact trench part.

5. The semiconductor apparatus according to claim 1, wherein on the front surface of the semiconductor substrate, the emitter region is extended from the second gate trench part to a direction of the second emitter non-contact trench part, and is terminated without reaching the second emitter non-contact trench part.

6. The semiconductor apparatus according to claim 2, wherein on the front surface of the semiconductor substrate, the emitter region is extended from the second gate trench part to a direction of the second emitter non-contact trench part, and is terminated without reaching the second emitter non-contact trench part.

7. The semiconductor apparatus according to claim 3, wherein on the front surface of the semiconductor substrate, the emitter region is extended from the second gate trench part to a direction of the second emitter non-contact trench part, and is terminated without reaching the second emitter non-contact trench part.

8. The semiconductor apparatus according to claim 1, comprising, in the semiconductor substrate;
a second conductivity type base region provided in contact with and below the emitter region;
a first conductivity type drift region provided in contact with and below the base region; and
a collector region provided below the drift region.

9. The semiconductor apparatus according to claim 2, comprising, in the semiconductor substrate;
a second conductivity type base region provided in contact with and below the emitter region;
a first conductivity type drift region provided in contact with and below the base region; and
a collector region provided below the drift region.

10. The semiconductor apparatus according to claim 3, comprising, in the semiconductor substrate;
a second conductivity type base region provided in contact with and below the emitter region;
a first conductivity type drift region provided in contact with and below the base region; and
a collector region provided below the drift region.

11. The semiconductor apparatus according to claim 5, comprising, in the semiconductor substrate;
a second conductivity type base region provided in contact with and below the emitter region;
a first conductivity type drift region provided in contact with and below the base region; and
a collector region provided below the drift region.

12. The semiconductor apparatus according to claim 8, wherein the base region is in contact with the drift region.

13. The semiconductor apparatus according to claim 8 comprising:
a second conductivity type well region provided above the drift region; and
an oxide film provided above the well region, wherein
the diode is provided above the oxide film.

14. The semiconductor apparatus according to claim 12 comprising:
a second conductivity type well region provided above the drift region; and
an oxide film provided above the well region, wherein
the diode is provided above the oxide film.

15. The semiconductor apparatus according to claim 13, wherein the diode includes a Zener diode, and is provided adjacent to the gate pad.

16. The semiconductor apparatus according to claim 1 comprising
a gate runner provided between the gate pad and a plurality of trench parts, wherein
the gate runner has a second conductivity type cathode peripheral region and a first conductivity type anode peripheral region, and
an anode of the diode includes the anode peripheral region, and a cathode of the diode includes the cathode peripheral region.

17. The semiconductor apparatus according to claim 2 comprising
a gate runner provided between the gate pad and a plurality of trench parts, wherein
the gate runner has a second conductivity type cathode peripheral region and a first conductivity type anode peripheral region, and
an anode of the diode includes the anode peripheral region, and a cathode of the diode includes the cathode peripheral region.

18. The semiconductor apparatus according to claim 3 comprising
a gate runner provided between the gate pad and a plurality of trench parts, wherein
the gate runner has a second conductivity type cathode peripheral region and a first conductivity type anode peripheral region, and
an anode of the diode includes the anode peripheral region, and a cathode of the diode includes the cathode peripheral region.

19. The semiconductor apparatus according to claim 5 comprising
a gate runner provided between the gate pad and a plurality of trench parts, wherein
the gate runner has a second conductivity type cathode peripheral region and a first conductivity type anode peripheral region, and
an anode of the diode includes the anode peripheral region, and a cathode of the diode includes the cathode peripheral region.

20. The semiconductor apparatus according to claim 16, wherein
at least one of the first emitter non-contact trench part and the second emitter non-contact trench part has an emitter non-contact trench conductive part set to the gate potential, wherein the emitter non-contact trench conductive part is integrally formed with the cathode peripheral region.
